(19) United States
(12) Patent Application Publication
(10) Pub. No.: US 2017/0012134 A1
(43) Pub. Date: Jan. 12, 2017

(54) SEMICONDUCTOR DEVICE AND MANUFACTURING METHOD OF SEMICONDUCTOR DEVICE

(71) Applicant: Japan Display Inc., Tokyo (JP)

(72) Inventors: Toshinari SASAKI, Tokyo (JP); Isao SUZUMURA, Tokyo (JP)

(21) Appl. No.: 15/189,279

(22) Filed: Jun. 22, 2016

(30) Foreign Application Priority Data
Jul. 9, 2015 (JP) 2015-138011

(51) Int. Cl. H01L 29/786; H01L 29/66; H01L 21/4763; H01L 29/417

(52) U.S. Cl. CPC H01L 29/7869; H01L 29/41733; H01L 29/66969; H01L 21/47635

(57) ABSTRACT

A manufacturing method of a semiconductor device includes forming an oxide semiconductor layer on an insulating layer, a part of the insulating layer being exposed from the oxide semiconductor layer, performing a plasma process by use of chlorine-containing gas on the part of the insulating layer exposed from the oxide semiconductor layer, and removing chlorine impurities from a surface layer of the exposed part of the insulating layer. The chlorine impurities may be removed by a first etching process performed by use of fluorine-containing gas. The fluorine-containing gas may contain CF₄ and CHF₃. The plasma process may be a second etching process performed by use of chlorine-containing gas.

### CROSS REFERENCE TO RELATED APPLICATIONS

This application is based upon and claims the benefit of priority from the prior Japanese Patent Application No. 2015-138011 filed on Jul. 9, 2015, the entire contents of which are incorporated herein by reference.

### FIELD

The present invention relates to a semiconductor device and a manufacturing method of the semiconductor device.

Recently, a driving circuit of a display device, a personal computer or the like includes a semiconductor device such as a transistor, a diode or the like as a microscopic switching element. Especially in a display device, a semiconductor device is used as a selective transistor that supplies a voltage or a current in accordance with the gray scale of each of pixels and also used in a driving circuit that selects a pixel to which the voltage or the current is to be supplied. The characteristics required of a semiconductor device vary in accordance with the use thereof. For example, a semiconductor device used as a selective transistor is required to have a low off-current or little variance in characteristics from another selective semiconductor. A semiconductor device used in a driving circuit is required to have a high on-current.

To be used in a display device as described above, a semiconductor device including a channel formed of amorphous silicon, low-temperature polysilicon or single crystalline silicon has been conventionally developed. The semiconductor device including a channel formed of amorphous silicon or low-temperature polysilicon is formed in a process of 600° C. or lower, and therefore can be formed by use of a glass substrate. Especially, a semiconductor device including a channel formed of amorphous silicon can be formed with a simpler structure and in a process of 400° C. or lower, and therefore can be formed, for example, by use of a large glass substrate referred to as an eighth-generation glass substrate (2160×2460 mm). However, such a semiconductor device including a channel formed of amorphous silicon has a low mobility and is not usable in a driving circuit.

A semiconductor device including a channel formed of low-temperature polysilicon or single crystalline silicon has a higher mobility than the semiconductor device including a channel formed of amorphous silicon, and therefore is usable as a selective transistor and also in a driving circuit. However, such a semiconductor device including a channel formed of low-temperature polysilicon or single crystalline silicon has a complicated structure and needs a complicated process to be manufactured. In addition, such a semiconductor device needs to be formed in a process of 500° C. or higher, and therefore cannot be formed by use of a large glass substrate as described above. A semiconductor device including a channel formed of amorphous silicon, low-temperature polysilicon or single crystalline silicon has a high off-current. In the case where such a semiconductor device is used as a selective transistor, it is difficult to keep the applied voltage for a long time.

For the above-described reasons, a semiconductor device including a channel formed of an oxide semiconductor, instead of amorphous silicon, low-temperature polysilicon or single crystalline silicon, has been progressively developed recently (e.g., Japanese Laid-Open Patent Publication No. 2010-062229). It is known that a semiconductor device including a channel formed of an oxide semiconductor can be formed with a simple structure and in a low-temperature process like a semiconductor device including a channel formed of amorphous silicon, and has a mobility higher than that of a semiconductor device including a channel formed of amorphous silicon. It is also known that such a semiconductor device including a channel formed of an oxide semiconductor has a very low off-current.

However, an oxide semiconductor is known to have a low tolerance against acid and to be etched when contacting an acidic aqueous solution. In the semiconductor device including a channel formed of an oxide semiconductor that is disclosed in Japanese Laid-Open Patent Publication No. 2010-062229, a conductive layer that is to be formed into a gate electrode, and source and drain electrodes is dry-etched with chlorine-containing gas. As a result of the dry etching, a chlorine-containing etching product is generated. When the chlorine-containing etching product is reacted with water, hydrochloric acid is generated. Hydrochloric acid etches the oxide semiconductor. In the case where the oxide semiconductor used for the channel is etched, characteristics desired for the semiconductor device are not provided. Even in the case where the oxide semiconductor is etched slightly and initial characteristics of the semiconductor device are not abnormal, the reliability of the semiconductor device may be lowered; for example, the characteristics may be fluctuated when the semiconductor device is irradiated with light.

### SUMMARY

A manufacturing method of a semiconductor device in an embodiment according to the present invention includes forming an oxide semiconductor layer on an insulating layer, a part of the insulating layer being exposed from the oxide semiconductor layer, performing a plasma process by use of chlorine-containing gas on the part of the insulating layer exposed from the oxide semiconductor layer, and removing chlorine impurities from a surface layer of the exposed part of the insulating layer.

A manufacturing method of a semiconductor device in an embodiment according to the present invention includes performing a plasma process by use of chlorine-containing gas on a part of an insulating layer, the part of the insulating layer being exposed, removing chlorine impurities from a surface layer of the part of the insulating layer, and forming an oxide semiconductor layer on the part of the insulating layer.

A semiconductor device in an embodiment according to the present invention includes a gate electrode, a gate insulating layer on the gate electrode, an oxide semiconductor layer facing the gate electrode with the gate insulating layer being therebetween, and source and drain electrodes on the oxide semiconductor layer, the source and drain electrodes being connected with the oxide semiconductor layer. A part of the gate insulating layer exposed from the oxide semiconductor layer and the source and drain electrodes has a thickness smaller than that of a part of the gate insulating layer below the oxide semiconductor layer and a part of the gate insulating layer below the source and drain electrodes.

A semiconductor device in an embodiment according to the present invention includes an underlying layer, source and drain electrodes on the underlying layer, an oxide semiconductor layer on a part of the underlying layer exposed from the source and drain electrodes, the oxide semiconductor layer being connected with the source and drain electrodes, a gate insulating layer on the oxide semiconductor layer, and a gate electrode facing the oxide semiconductor layer with the gate insulating layer being therebetween. A part of the underlying layer below the oxide semiconductor layer has a thickness smaller than that of a part of the underlying layer below the source and drain electrodes.

### BRIEF DESCRIPTION OF DRAWINGS

FIG. 1 is a plan view showing an overview of a semiconductor device in an embodiment according to the present invention;

FIG. 2 is a cross-sectional view showing an overview of the semiconductor device in the embodiment according to the present invention, taken along line A-A′ in FIG. 1;

FIG. 3 is a cross-sectional view showing an overview of the semiconductor device in the embodiment according to the present invention, taken along line B-B′ in FIG. 1;

FIG. 4 is a cross-sectional view taken along line A-A′ showing a step of forming a gate electrode in a manufacturing method of the semiconductor device in the embodiment according to the present invention;

FIG. 5 is a cross-sectional view taken along line B-B′ showing the step of forming the gate electrode in the manufacturing method of the semiconductor device in the embodiment according to the present invention;

FIG. 6 is a cross-sectional view taken along line A-A′ showing a step of forming a gate insulating layer in the manufacturing method of the semiconductor device in the embodiment according to the present invention;

FIG. 7 is a cross-sectional view taken along line B-B showing the step of forming the gate insulating layer in the manufacturing method of the semiconductor device in the embodiment according to the present invention;

FIG. 8 is a cross-sectional view taken along line A-A′ showing a step of forming an oxide semiconductor layer in the manufacturing method of the semiconductor device in the embodiment according to the present invention;

FIG. 9 is a cross-sectional view taken along line B-B′ showing the step of forming the oxide semiconductor layer in the manufacturing method of the semiconductor device in the embodiment according to the present invention;

FIG. 10 is a cross-sectional view taken along line A-A′ showing a step of forming source and drain electrodes in the manufacturing method of the semiconductor device in the embodiment according to the present invention;

FIG. 11 is a cross-sectional view taken along line B-B′ showing the step of forming the source and drain electrodes in the manufacturing method of the semiconductor device in the embodiment according to the present invention;

FIG. 12 is a cross-sectional view taken along line A-A′ showing a step of performing a chlorine removal process of removing chlorine impurities in the manufacturing method of the semiconductor device in the embodiment according to the present invention;

FIG. 13 is a cross-sectional view taken along line B-B′ showing the step of performing the chlorine removal process of removing the chlorine impurities in the manufacturing method of the semiconductor device in the embodiment according to the present invention;

FIG. 14 is a plan view showing an overview of a semiconductor device in an embodiment according to the present invention;

FIG. 15 is a cross-sectional view showing an overview of the semiconductor device in the embodiment according to the present invention, taken along line C-C′ in FIG. 14;

FIG. 16 is a cross-sectional view showing an overview of the semiconductor device in the embodiment according to the present invention, taken along line D-D′ in FIG. 14;

FIG. 17 is a cross-sectional view taken along line C-C′ showing a step of forming source and drain electrodes in a manufacturing method of the semiconductor device in the embodiment according to the present invention;

FIG. 18 is a cross-sectional view taken along line D-D′ showing the step of forming the source and drain electrodes in the manufacturing method of the semiconductor device in the embodiment according to the present invention;

FIG. 19 is a cross-sectional view taken along line C-C′ showing a step of performing a chlorine removal process of removing chlorine impurities in the manufacturing method of the semiconductor device in the embodiment according to the present invention;

FIG. 20 is a cross-sectional view taken along line D-D′ showing the step of performing the chlorine removal process of removing the chlorine impurities in the manufacturing method of the semiconductor device in the embodiment according to the present invention;

FIG. 21 is a cross-sectional view taken along line C-C′ showing a step of forming an oxide semiconductor layer in the manufacturing method of the semiconductor device in the embodiment according to the present invention;

FIG. 22 is a cross-sectional view taken along line D-D′ showing the step of forming the oxide semiconductor layer in the manufacturing method of the semiconductor device in the embodiment according to the present invention;

FIG. 23 is a cross-sectional view taken along line C-C′ showing a step of forming a gate insulating layer in the manufacturing method of the semiconductor device in the embodiment according to the present invention;

FIG. 24 is a cross-sectional view taken along line D-D′ showing the step of forming the gate insulating layer in the manufacturing method of the semiconductor device in the embodiment according to the present invention;

FIG. 25 is a cross-sectional view taken along line C-C′ showing a step of forming a gate electrode in the manufacturing method of the semiconductor device in the embodiment according to the present invention;

FIG. 26 is a cross-sectional view taken along line D-D′ showing the step of forming the gate electrode in the manufacturing method of the semiconductor device in the embodiment according to the present invention;

FIG. 27 is a cross-sectional view showing an overview of a semiconductor device in an embodiment according to the present invention, taken along line C-C′ in FIG. 14;

FIG. 28 is a cross-sectional view showing an overview of the semiconductor device in the embodiment according to the present invention, taken along line D-D′ in FIG. 14;

FIG. 29 is a cross-sectional view taken along line C-C′ showing a step of forming an oxide semiconductor layer in a manufacturing method of the semiconductor device in the embodiment according to the present invention;

FIG. 30 is a cross-sectional view taken along line D-D′ showing the step of forming the oxide semiconductor layer in the manufacturing method of the semiconductor device in the embodiment according to the present invention;

FIG. 31 is a cross-sectional view taken along line C-C′ showing a step of forming source and drain electrodes in the manufacturing method of the semiconductor device in the embodiment according to the present invention;

FIG. 32 is a cross-sectional view taken along line D-D′ showing the step of forming the source and drain electrodes in the manufacturing method of the semiconductor device in the embodiment according to the present invention;

FIG. 33 is a cross-sectional view taken along line C-C′ showing a step of performing a chlorine removal process of removing chlorine impurities in the manufacturing method of the semiconductor device in the embodiment according to the present invention;

FIG. 34 is a cross-sectional view taken along line D-D′ showing the step of performing the chlorine removal process of removing the chlorine impurities in the manufacturing method of the semiconductor device in the embodiment according to the present invention;

FIG. 35 is a cross-sectional view taken along line C-C′ showing a step of forming a gate insulating layer in the manufacturing method of the semiconductor device in the embodiment according to the present invention;

FIG. 36 is a cross-sectional view taken along line D-D′ showing the step of forming the gate insulating layer in the manufacturing method of the semiconductor device in the embodiment according to the present invention;

FIG. 37 is a cross-sectional view taken along line C-C′ showing a step of forming a gate electrode in the manufacturing method of the semiconductor device in the embodiment according to the present invention;

FIG. 38 is a cross-sectional view taken along line D-D′ showing the step of forming the gate electrode in the manufacturing method of the semiconductor device in the embodiment according to the present invention;

FIG. 39A shows a manufacturing method of samples in an example according to the present invention and a comparative example;

FIG. 39B shows the manufacturing method the samples in the example according to the present invention and the comparative example;

FIG. 39C shows the manufacturing method of the samples in the example according to the present invention and the comparative example;

FIG. 40A shows the manufacturing method of the samples in the example according to the present invention and the comparative example;

FIG. 40B shows the manufacturing method of the samples in the example according to the present invention and the comparative example;

FIG. 41 shows the ToF-SIMS analysis results obtained from the example samples;

FIG. 42 shows the ToF-SIMS analysis results obtained from the comparative example samples;

FIG. 43 shows the transistor reliability test results obtained from the example samples;

FIG. 44 shows the transistor reliability test results obtained from the comparative example samples;

FIG. 45 shows an optical micrograph of a transistor as an example sample;

FIG. 46 is a schematic cross-sectional view of FIG. 45 taken along line E-E in FIG. 45;

FIG. 47 shows an optical micrograph of a transistor obtained as a comparative example sample;

FIG. 48 is a schematic cross-sectional view of FIG. 47 taken along line E-E′ in FIG. 47;

FIG. 49 shows an optical micrograph of a transistor as an example sample;

FIG. 50 is a schematic cross-sectional view of FIG. 49 taken along line F-F′ in FIG. 49;

FIG. 51 shows an optical micrograph of a transistor as a comparative example sample; and

FIG. 52 is a schematic cross-sectional view of FIG. 51 taken along line F-F′ in FIG. 51.

### DESCRIPTION OF EMBODIMENTS

Hereinafter, embodiments of the present invention will be described with reference to the drawings. The disclosure is merely exemplary, and alternations and modifications readily conceivable by a person of ordinary skill in the art without departing from the gist of the present invention are duly encompassed in the scope of the present invention. In the drawings, components may be shown schematically regarding the width, thickness, shape and the like, instead of being shown in accordance with the actual sizes, for the sake of clear illustration. The drawings are merely exemplary and do not limit the interpretations of the present invention in any way. In the specification and the drawings, components that are substantially the same as those shown in a previous drawing(s) bear the identical reference signs thereto, and detailed descriptions thereof may be omitted. The following embodiments are presented for the purpose of providing a highly reliable semiconductor device and a manufacturing method of such a semiconductor device.

In the following description of the embodiments, the expression that “a first member and a second member are connected with each other” indicates that at least the first member and the second member are electrically connected with each other. Namely, the first member and the second member may be physically connected with each other directly, or another member may be provided between the first member and the second member.

### Embodiment 1

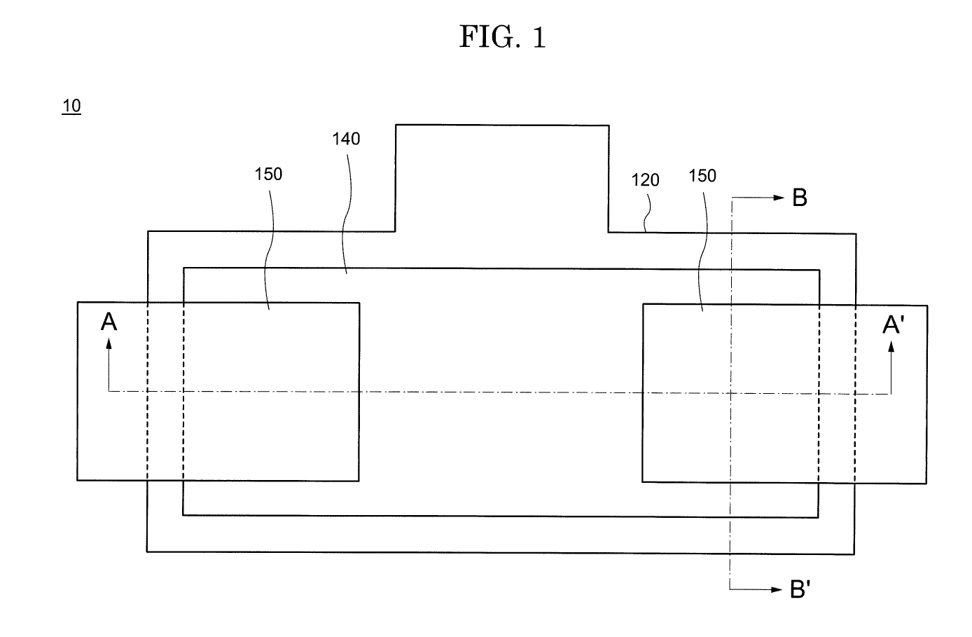

With reference to FIG. 1 through FIG. 3, an overview of a semiconductor device 10 in embodiment 1 according to the present invention will be described. The semiconductor device 10 in embodiment 1 is usable in a pixel or a driving circuit of a liquid crystal display device (LCD), a spontaneous emission display device using an organic light-emitting diode (OLED) such as an organic EL element, a quantum dot or the like for a display unit, or a reflection-type display device such as an electronic paper or the like.

It should be noted that a semiconductor device according to the present invention is not limited to being used in a display device, and may be used in, for example, an integrated circuit (IC) such as a microprocessing unit (MPU) or the like. The semiconductor device 10 in embodiment 1 has a structure including a channel formed of an oxide semiconductor. In embodiment 1, the semiconductor device 10 is a transistor. This does not limit the semiconductor device according to the present invention to being a transistor.

### [Structure of the Semiconductor Device 10]

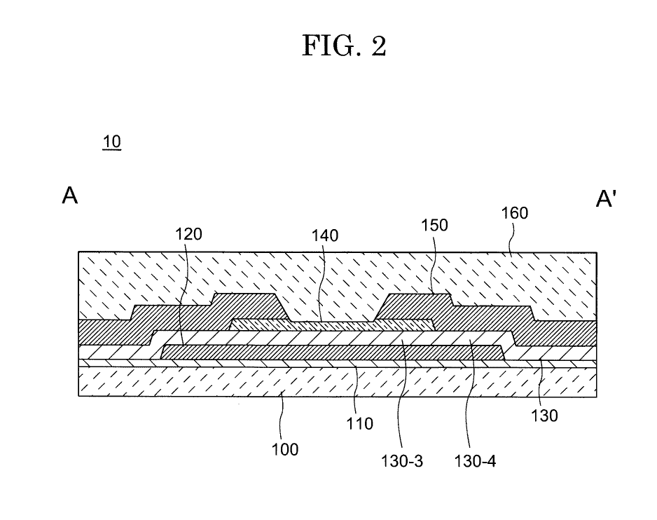

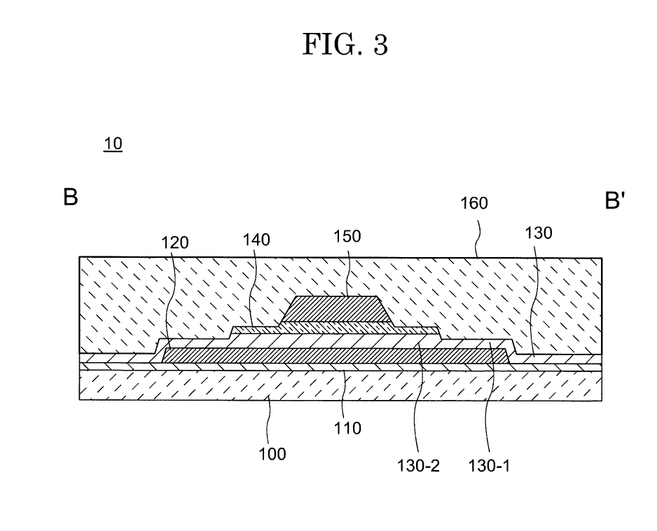

FIG. 1 is a plan view showing an overview of the semiconductor device 10 in embodiment 1 according to the present invention. FIG. 2 is a cross-sectional view showing an overview of the semiconductor device 10 in embodiment 1 according to the present invention, taken along line A-A′ in FIG. 1, FIG. 3 is a cross-sectional view showing an overview of the semiconductor device 10 in embodiment 1 according to the present invention, taken along line B-B′ in FIG. 1. As shown in FIG. 1 through FIG. 3, the semiconductor device 10 includes a substrate 100, an underlying layer 110, a gate electrode 120, a gate insulating layer 130, an oxide semiconductor layer 140, source and drain electrodes 150, and a protective layer 160. The semiconductor device 10 is a bottom gate-type transistor.

The underlying layer 110 is located on the substrate 100. The gate electrode 120 is located on the underlying layer 110. The gate insulating layer 130 is located on the gate electrode 120 and the underlying layer 110. The oxide semiconductor layer 140 is located to face the gate electrode 120 with the gate insulating layer 130 being provided therebetween. As shown in FIG. 1, as seen in a plan view, the oxide semiconductor layer 140 is located inner to the gate electrode 120.

As shown in FIG. 3, a gate insulating layer 130-1 has a smaller thickness than that of a gate insulating layer 130-2. The gate insulating layer 130-1 is located in an area where neither the oxide semiconductor layer 140 nor the source and drain electrodes 150 are located, namely, an area exposed from the oxide semiconductor layer 140 and the source and drain electrodes 150. The gate insulating layer 130-2 is located below the oxide semiconductor layer 140. As shown in FIG. 2, a gate insulating layer 130-3 has the same thickness as that of a gate insulating layer 130-4. The gate insulating layer 130-3 is located below the oxide semiconductor layer 140. The gate insulating layer 130-4 is located below the source and drain electrodes 150.

As shown in FIG. 2, the source and drain electrodes 150 are located on the oxide semiconductor layer 140 and a part of the gate insulating layer 130 where the oxide semiconductor layer 140 is not located. The source and drain electrodes 150 are connected with the oxide semiconductor layer 140. The source and drain electrodes 150 include a pair of electrodes separated from each other with a distance. In accordance with the applied voltage, one of the pair of electrodes is the source electrode, and the other electrode is the drain electrode. The distance between the pair of electrodes corresponds to a channel length of the semiconductor device 10. A part of the oxide semiconductor layer 140 that is located between the pair of electrodes has a thickness smaller than that of a part of the oxide semiconductor layer 140 that is below the source and drain electrodes 150.

The protective layer 160 covers the gate insulating layer 130, the oxide semiconductor layer 140, and the source and drain electrodes 150.

The substrate 100 may be formed of a glass substrate. Alternatively, the substrate 100 may be formed of a light-transmissive insulating material such as quartz, sapphire, a resin or the like. In the case where the semiconductor device 10 is used in an integrated circuit, not in a display device, the substrate 100 may be formed of a non-light-transmissive material, for example, a semiconductor such as silicon, silicon carbide, a compound semiconductor or the like, or a conductive material such as stainless steel or the like.

The underlying layer 110 may be formed of a material that suppresses diffusion of impurities from the substrate 100 into the oxide semiconductor layer 140. For example, the underlying layer 110 may be formed of silicon nitride (SiNₓ), silicon nitride oxide (SiNₓO_{y}), silicon oxide (SiOₓ), silicon oxide nitride (SiOₓN_{y}), aluminum nitride (AlNₓ), aluminum nitride oxide (AlNₓO_{y}), aluminum oxide (AlOₓ), aluminum oxide nitride (AlOₓN_{y}), or the like (x and y each represent an arbitrary value). Alternatively, the underlying layer 110 may have a structure including a stack of films of any of such materials.

SiOₓN_{y} and AlOₓN_{y} are respectively a silicon compound and an aluminum compound containing nitrogen (N) at a lower content than oxygen (O). SiNₓO_{y} and AlNₓO_{y} are respectively a silicon compound and an aluminum compound containing oxygen at a lower content than nitrogen.

The underlying layer 110 described above as an example may be formed by a PVD (Physical Vapor Deposition) method or a CVD (Chemical Vapor Deposition) method. Examples of the usable PVD method include sputtering, vacuum vapor deposition, electron beam vapor deposition, plating, molecular beam epitaxy, and the like. Examples of the usable CVD method include thermal CVD, plasma CVD, catalyst CVD (Cat (catalytic)-CVD or hot-wire CVD), and the like.

The gate electrode 120 may be formed of a commonly used metal material or a commonly used conductive semiconductor material. For example, the gate electrode 120 may be formed of aluminum (Al), titanium (Ti), chromium (Cr), cobalt (Co), nickel (Ni), zinc (Zn), molybdenum (Mo), indium (In), tin (Sn), hafnium (Hf), tantalum (Ta), tungsten (W), platinum (Pt), bismuth (Bi), or the like. 0Alternatively, the gate electrode 120 may be formed of an alloy of such materials or a nitride of such materials. Still alternatively, the gate electrode 120 may be formed of a conductive oxide semiconductor such as ITO (indium tin oxide), IGO (indium gallium oxide), IZO (indium zinc oxide), GZO (zinc oxide containing gallium as a dopant), or the like. The gate electrode 120 may have a structure including a stack of films of any of such materials.

Preferably, the material used for the gate electrode 120 is resistant to a heat treatment step in a manufacturing process of a semiconductor device including a channel formed of an oxide semiconductor, and has a work function with which the transistor is of an enhancement type that is turned off when a voltage of 0 V is applied to the gate electrode 120.

The gate insulating layer 130 may be formed of an inorganic insulating material such as SiOₓ, SiNₓ, SiOₓN_{y}, SiNₓO_{y}, AlOₓ, AlNₓ, AlOₓN_{y}, AlNₓO_{y}, or the like, like the underlying layer 110. Alternatively, the gate insulating layer 130 may have a stack of films of any of such materials. The gate insulating layer 130 may be formed by substantially the same method as that of the underlying layer 110. The gate insulating layer 130 and the underlying layer 110 may be formed of the same material as, or different materials from, each other.

The oxide semiconductor layer 140 may be formed of a metal oxide material having the characteristics of a semiconductor. For example, the oxide semiconductor layer 140 may be formed of an oxide semiconductor containing indium (In), gallium (Ga), zinc (Zn) and oxygen (O). Especially, the oxide semiconductor layer 140 may be formed of an oxide semiconductor having a composition ratio of In:Ga:Zn:O=1:1:1:4. It should be noted that the oxide semiconductor used in the present invention and containing In, Ga, Zn and O is not limited to having the above-described composition ratio. An oxide semiconductor having a different composition ratio is also usable. For example, in order to improve the mobility, the ratio of In may be increased. In order to increase the bandgap and thus decrease the influence of light, the ratio of Ga may be increased.

The oxide semiconductor containing In, Ga, Zn and O may contain another element added thereto. For example, a metal element such as Al, Sn or the like may be added. Instead of the above-described oxide semiconductor, zinc oxide (ZnO), nickel oxide (NiO), tin oxide (SnO₂), titanium oxide (TiO₂), vanadium oxide (VO₂), indium oxide (In₂O₃), strontium titanate (SrTiO₃), or the like may be used. The oxide semiconductor layer 140 may be amorphous or crystalline. Alternatively, the oxide semiconductor layer 140 may have a mixed phase of an amorphous phase and a crystalline phase.

The source and drain electrodes 150 may be formed of a commonly used metal material or a commonly used conductive semiconductor material, like the gate electrode 120. For example, the source and drain electrodes 150 may be formed of Al, Ti, Cr, Co, Ni, Zn, Mo, In, Sn, Hf, Ta, W, Pt, Bi, or the like. Alternatively, the source and drain electrodes 150 may be formed of an alloy of such materials or a nitride of such materials, Still alternatively, the source and drain electrodes 150 may be formed of a conductive oxide semiconductor such as ITO, IGO, IZO, GZO, or the like. The source and drain electrodes 150 may have a structure including a stack of films of any of such materials. Preferably, the material used for the source and drain electrodes 150 is resistant to a heat treatment step in a manufacturing process of a semiconductor device including a channel formed of an oxide semiconductor, and has a low contact resistance with the oxide semiconductor layer 140. As a material having a good electric contact with the oxide semiconductor layer 140, a metal material having a work function smaller than that of the oxide semiconductor layer 140 is usable for the source and drain electrodes 150.

The protective layer 160 may be formed of an inorganic insulating material such as SiOₓ, SiNₓ, SiOₓN_{y}, SiNₓO_{y}, AlOₓ, AlNₓ, AlOₓN_{y}, AlNₓO_{y}, or the like, like the underlying layer 110 and the gate insulating layer 130. Instead of the above-listed inorganic insulating materials, the protective layer 160 may be formed of a TEOS layer or an organic insulating material. The protective layer 160 may be formed by substantially the same method as that of the underlying layer 110.

The “TEOS layer” refers to a CVD layer formed of TEOS (Tetra Ethyl Ortho Silicate), and has an effect of alleviating the steps of, and thus flattening, a layer therebelow. The underlying layer 110 and the gate insulating layer 130 may be formed of a TEOS layer.

Examples of the usable organic insulating material include a polyimide resin, an acrylic resin, an epoxy resin, a silicone resin, a fluorine resin, a siloxane resin, and the like. The protective layer 160 may be formed of a single layer or a stack of films of such materials. For example, the protective layer 160 may include a stack of an inorganic insulating material and an organic insulating material.

### [Manufacturing Method of the Semiconductor Device 10]

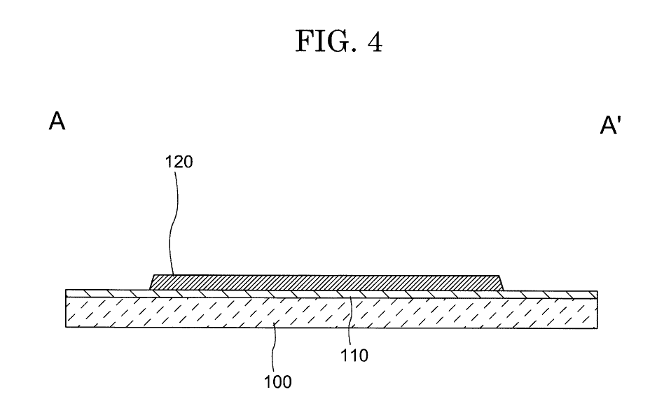

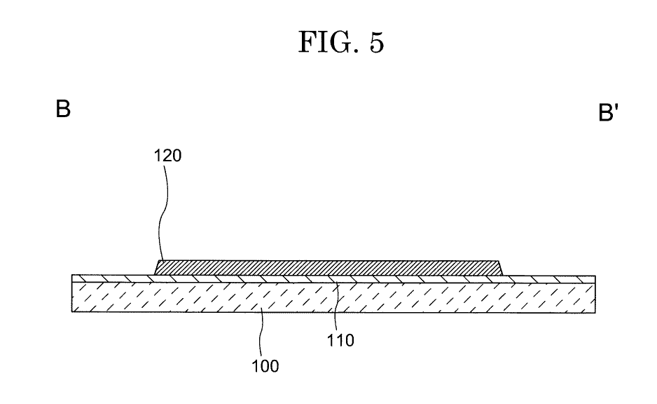

With reference to FIG. 4 through FIG. 13, a manufacturing method of the semiconductor device 10 in embodiment 1 according to the present invention will be described. FIG. 4 through FIG. 13 are each a cross-sectional view taken along line A-A′ or B-B′ in FIG. 1. FIG. 4 and FIG. 5 are respectively a 1cross-sectional view taken along line A-A′ and a cross-sectional view taken along line B-B′ showing a step of forming the gate electrode 120 in the manufacturing method of the semiconductor device 10 in embodiment 1 according to the present invention. Referring to FIG. 4 and FIG. 5, the underlying layer 110 and a film for the gate electrode 120 are formed on the substrate 100, and patterning is performed by photolithography and etching to form the gate electrode 120 shown in FIG. 1. Preferably, the etching for forming the gate electrode 120 is performed under the condition that the etching rate ratio of the gate electrode 120 with respect to the underlying layer 110 is high.

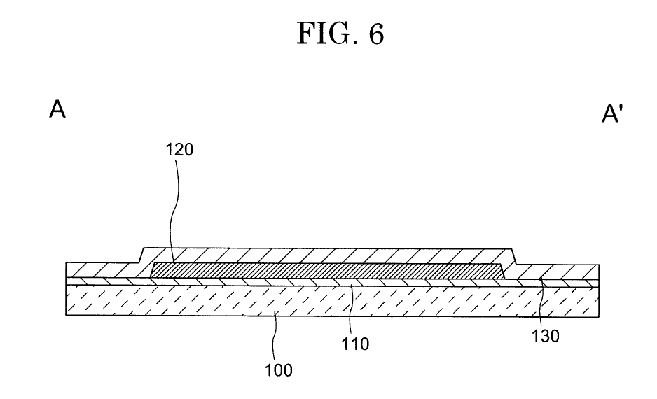

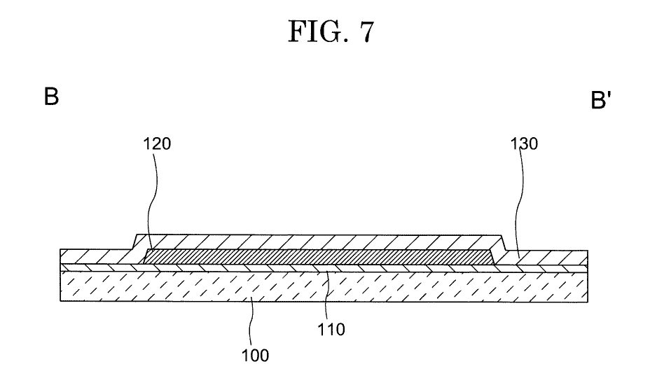

FIG. 6 and FIG. 7 are respectively a cross-sectional view taken along line A-A′ and a cross-sectional view taken along line B-B′ showing a step of forming the gate insulating layer 130 in the manufacturing method of the semiconductor device 10 in embodiment 1 according to the present invention. Referring to FIG. 6 and FIG. 7, the gate insulating layer 130 is formed on the underlying layer 110 and the gate electrode 120. An opening may be formed in the gate insulating layer 130.

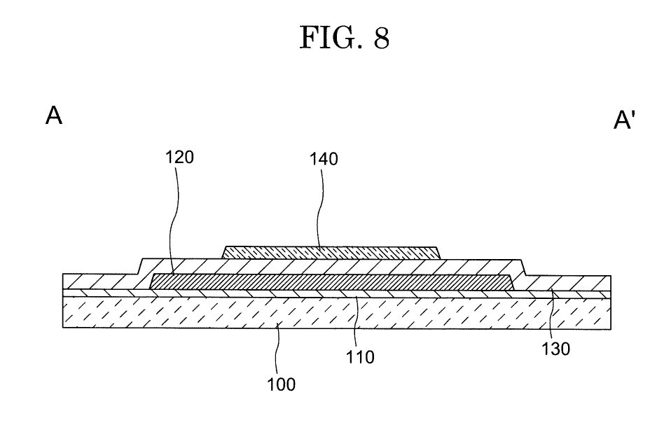

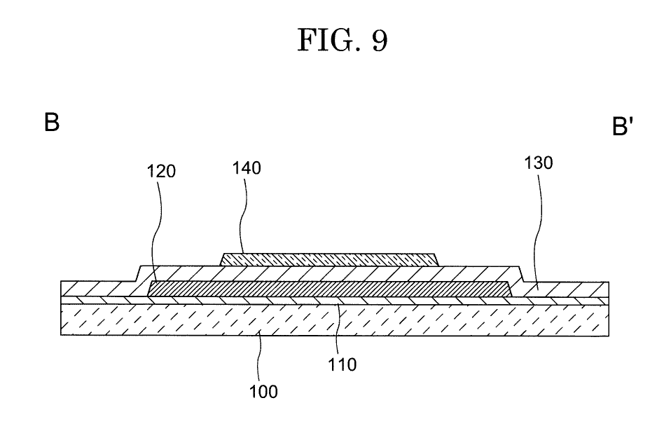

FIG. 8 and FIG. 9 are respectively a cross-sectional view taken along line A-A and a cross-sectional view taken along line B-B′ showing a step of forming the oxide semiconductor layer 140 in the manufacturing method of the semiconductor device 10 in embodiment 1 according to the present invention. Referring to FIG. 8 and FIG. 9, a film for the oxide semiconductor layer 140 is formed on the gate insulating layer 130, and patterning is performed by photolithography and etching to form the oxide semiconductor layer 140 shown in FIG. 1.

The oxide semiconductor layer 140 may be formed by sputtering. The etching performed to form the oxide semiconductor layer 140 may be dry etching or wet etching. In the case where the oxide semiconductor layer 140 is formed by wet etching, an etchant containing oxalic acid, an etchant containing phosphoric acid, or an etchant containing hydrogen fluoride may be used.

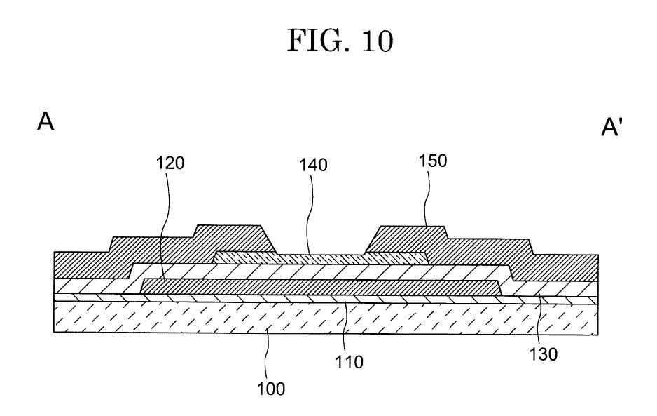

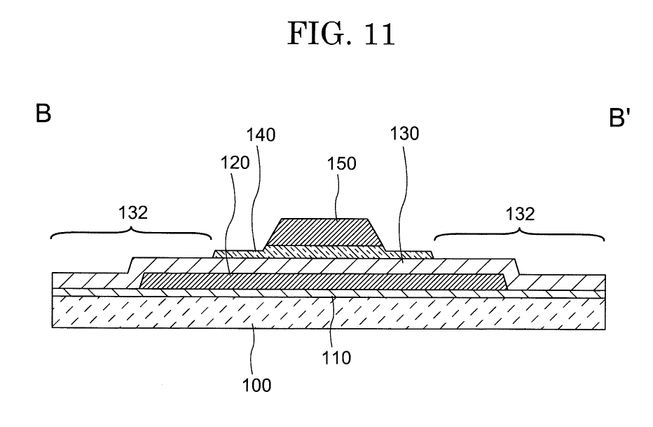

FIG. 10 and FIG. 11 are respectively a cross-sectional view taken along line A-A′ and a cross-sectional view taken along line B-B′ showing a step of forming the source and drain electrodes 150 in the manufacturing method of the semiconductor device 10 in embodiment 1 according to the present invention. Referring to FIG. 10 and FIG. 11, a film for the source and drain electrodes 150 is formed on the gate insulating layer 130 and the oxide semiconductor layer 140, and patterning is performed by photolithography and etching to form the source and drain electrodes 150 shown in FIG. 1.

The etching for forming the source and drain electrodes 150 may be performed by use of chlorine-containing gas. As a result of the dry etching, the source and drain electrodes 150 are formed, and a part of the oxide semiconductor layer 140 and a part of the gate insulating layer 130 that are below the etched-away part of the film for the source and drain electrodes 150 are exposed. In FIG. 10 and FIG. 11, the part of the oxide semiconductor layer 140 that is exposed by the dry etching is half-etched in order to suppress the etching for forming the source and drain electrodes 150 from being left partially undone. Namely, the oxide semiconductor layer 140 is etched so that the part of the oxide semiconductor layer 140 exposed from the source and drain electrodes 150 has a thickness smaller than that of the part of the oxide semiconductor layer 140 located below the source and drain electrodes 150. There is no specific limitation on the thickness of the half-etched part of the oxide semiconductor layer 140. The thickness of the half-etched part of the oxide semiconductor layer 140 may be greater than, or equal to, half of the thickness of the non-half-etched part of the oxide semiconductor layer 140, or may be less than, or equal to, half of the thickness of the non-half-etched part of the oxide semiconductor layer 140.

Examples of the gas usable for the dry etching include chlorine gas (Cl₂), boron trichloride gas (BCl₃), carbon tetrachloride gas (CCl₄) and the like. These types of gas may be used independently or as a mixture thereof. For example, the dry etching may be performed by use of mixed gas of Cl₂ and BCl₃. The dry etching may be reactive ion etching (RIE), or a plasma process performed by use of any of the above-described types of gas.

With the dry etching, the gate insulating layer 130 formed of an inorganic insulating material such as, for example, SiOₓ, SiNₓ, SiOₓN_{y}, SiNₓO_{y}, AlOₓ, AlNₓ, AlOₓN_{y}, AlNₓO_{y}, or the like is not etched almost at all. Namely, a part of the gate insulating layer 130 in a region 132 shown in FIG. 11 that is exposed from the oxide semiconductor layer 140 is not etched almost at all. Even if the gate insulating layer 130 is etched by the dry etching, the etching amount of the part of the gate insulating layer 130 in the region 132 is smaller than the etching amount of the oxide semiconductor layer 140.

The part of the gate insulating layer 130 that is in the region 132 is exposed to a dry etching atmosphere. In other words, the part of the gate insulating layer 130 that is in the region 132 is exposed to plasma using chlorine-containing gas. Therefore, an etching product containing chlorine is attached to a surface of the part of the gate insulating layer 130 that is in the region 132. Alternatively, chlorine atoms or chlorine ions are implanted into an area having a certain depth from the surface of the part of the gate insulating layer 130 that is in the region 132. The etching product and the implanted chlorine atoms or chlorine ions are considered as chlorine impurities. The chlorine impurities are considered to be present in a surface layer of the gate insulating layer 130. The chlorine impurities are not limited to being generated by the dry etching performed to form the source and drain electrodes 150, and may be generated by another type of plasma process performed by use of chlorine-containing gas.

When the chlorine impurities are reacted with water, hydrochloric acid is generated. When, for example, the substrate in FIG. 10 and FIG. 11 is washed, the chlorine impurities present in the part of the gate insulating layer 130 that is in the region 132 are reacted with water to generate hydrochloric acid. Hydrochloric acid generated in the region 132 etches the part of the oxide semiconductor layer 140 exposed from the source and drain electrodes 150. In addition, when the substrate is removed outside from a vacuum device used for dry etching or the like, the chlorine impurities are reacted with moisture contained in the air to generate hydrochloric acid. Also, the chlorine impurities are reacted with moisture contained in the gate insulating layer 130 or the protective layer 160 formed on the gate insulating layer 130 in a later step, and as a result, hydrochloric acid is generated. Therefore, the chlorine impurities need to be removed in order to prevent the generation of hydrochloric acid. In this and the following descriptions of manufacturing methods of semiconductor devices in embodiments according to the present invention, an assembly of the substrate 100 (100A, 100B) and the layer(s) formed thereon at each step will be referred to as the “substrate” for the sake of convenience.

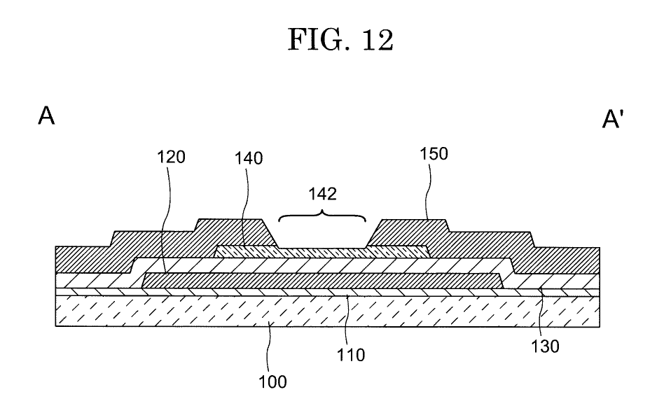

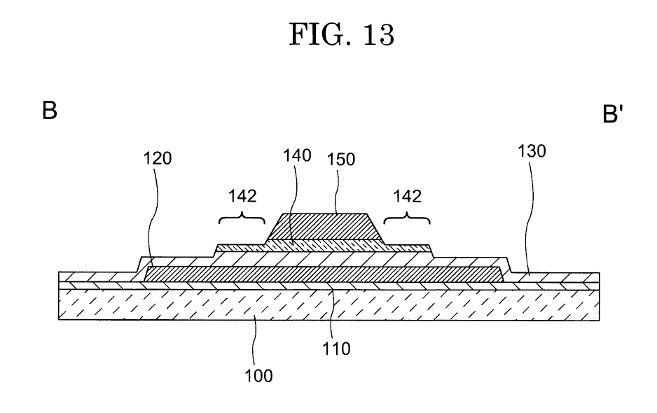

FIG. 12 and FIG. 13 are respectively a cross-sectional view taken along line A-A and a cross-sectional view taken along line B-B′ showing a step of performing a chlorine removal process of removing the chlorine impurities in the manufacturing method of the semiconductor device 10 in embodiment 1 according to the present invention. Referring to FIG. 12 and FIG. 13, the chlorine impurities present in the surface layer of the part of the gate insulating layer 130 that is in the region 132 (see FIG. 11) exposed from the oxide semiconductor layer 140 are removed.

The chlorine removal process may be performed by dry etching by use of fluorine-containing gas. With the dry etching, the part of the gate insulating layer 130 that is in the region 132, in which the chlorine impurities are present, namely, the part of the gate insulating layer 130 exposed from the source and drain electrodes 150 and the oxide semiconductor layer 140, is half-etched. The dry etching removes the chlorine impurities from the surface layer of the part of the gate insulating layer 130 that is in the region 132. There is no specific limitation on the thickness of the half-etched part of the gate insulating layer 130. The thickness of the half-etched part of the gate insulating layer 130 may be greater than, or equal to, half of the thickness of the non-half-etched part of the gate insulating layer 130, or may be less than, or equal to, half of the thickness of the non-half-etched part of the gate insulating layer 130.

Examples of the gas usable for the dry etching for the chlorine removal process include carbon tetrafluoride gas (CF₄), methane trifluoride gas (CHF₃), fluorocarbon gas (C₂F₅), sulfur hexafluoride gas (SF₆) and the like. These types of gas may be used independently or as a mixture thereof. For example, the dry etching may be performed by use of mixed gas of CF₄ and CHF₃. The dry etching may be reactive ion etching (RIE), or a plasma process performed by use of any of the above-described types of gas.

With the dry etching performed for the chlorine removal process, the oxide semiconductor layer 140 is not etched almost at all. Namely, a part of the oxide semiconductor layer 140 in a region 142 shown in FIG. 12 and FIG. 13 that is exposed from the source and drain electrodes 150 is not etched almost at all. Even if the oxide semiconductor layer 140 is etched by the dry etching for the chlorine removal process, the etching amount of the part of the oxide semiconductor layer 140 in the region 142 is smaller than the etching amount of the gate insulating layer 130.

The depth of the half-etching performed on the gate insulating layer 130 may be determined in accordance with the position of the chlorine impurities (e.g., depth profile of chlorine atoms by a SIMS analysis). In the case where, for example, the chlorine impurities are present in the surface layer of the gate insulating layer 130, it is sufficient that the chlorine impurities are removed by the dry etching and the gate insulating layer 130 is etched even slightly. By contrast, in the case where chlorine atoms or chlorine ions are implanted into an area having a certain depth from the surface of the gate insulating layer 130, it is preferable that the gate insulating layer 130 is etched to a level deeper than the area into which the chlorine atoms or the chlorine ions are implanted.

In the above example, the chlorine removal process is performed by dry etching by use of fluorine-containing gas. The method of the chlorine removal process is not limited to this. For example, the chlorine removal process may be performed by dry etching by use of another type of gas not containing chlorine. Instead of dry etching, plasma process, reverse sputtering or the like is usable for the chlorine removal process. Alternatively, the chlorine removal process may be performed by wet etching by use of a liquid chemical.

When the chlorine impurities are reacted with water, hydrochloric acid is generated. Therefore, the substrate may be kept in vacuum between the dry etching step for forming the source and drain electrodes 150 and the chlorine removal step. Keeping the substrate between these two steps suppresses hydrochloric acid from being generated due to moisture in the air.

The protective layer 160 is formed on the entirety of a surface of the substrate shown in FIG. 12 and FIG. 13. With the above-described manufacturing method, the semiconductor device 10 in embodiment 1 according to the present invention is manufactured.

As described above, with the manufacturing method of the semiconductor device 10 in embodiment 1 according to the present invention, the chlorine impurities generated in the surface layer of the gate insulating layer 130 by the plasma process performed by use of chlorine-containing gas are removed. Therefore, generation of chlorine is suppressed in later steps, and thus the oxide semiconductor layer 140 is suppressed from being etched. The semiconductor device 10 manufactured by such a method is highly reliable.

### Embodiment 2

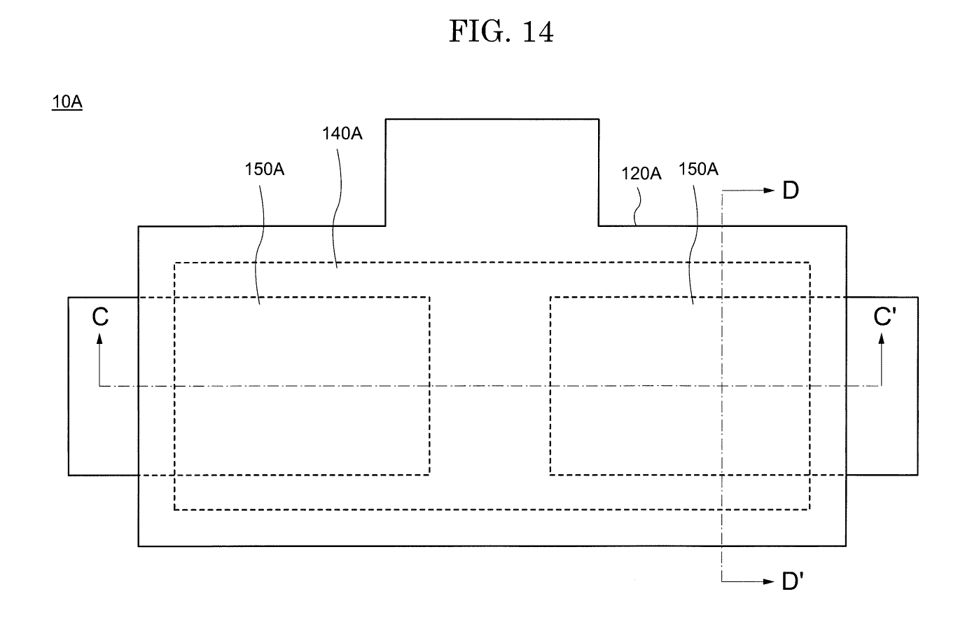

With reference to FIG. 14 through FIG. 16, an overview of a semiconductor device 10A in embodiment 2 according to the present invention will be described. The semiconductor device 10A in embodiment 2 is usable in a pixel or a driving circuit of a liquid crystal display device (LCD), a spontaneous emission display device using an organic light-emitting diode (OLED) such as an organic EL element, a quantum dot or the like for a display unit, or a reflection-type display device such as an electronic paper or the like.

### [Structure of the Semiconductor Device 10A]

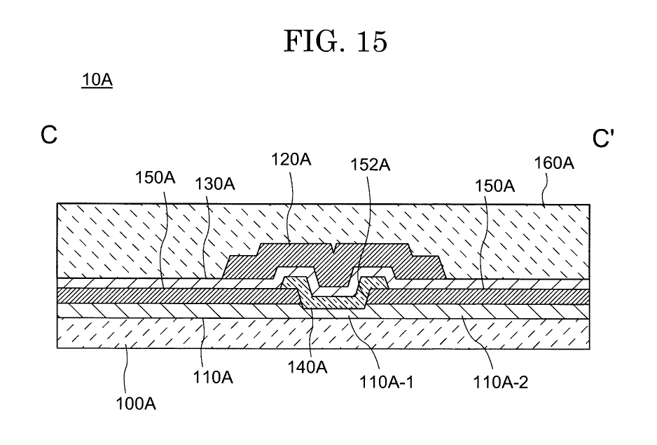

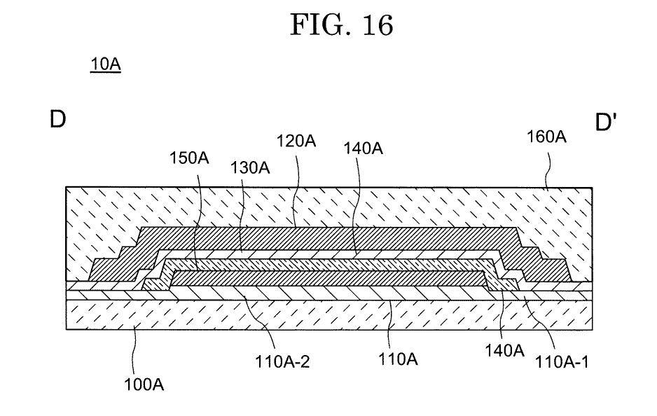

FIG. 14 is a plan view showing an overview of the semiconductor device 10A in embodiment 2 according to the present invention. FIG. 15 is a cross-sectional view showing an overview of the semiconductor device 10A in embodiment 2 according to the present invention, taken along line C-C′ in FIG. 14. FIG. 16 is a cross-sectional view showing an overview of the semiconductor device 10A in embodiment 2 according to the present invention, taken along line D-D′ in FIG. 14. As shown in FIG. 14 through FIG. 16, the semiconductor device 10A includes a substrate 100A, an underlying layer 110A, source and drain electrodes 150A, an oxide semiconductor layer 140A, a gate insulating layer 130A, a gate electrode 120A, and a protective layer 160A. The semiconductor device 10A is a top gate-type transistor.

The underlying layer 110A is located on the substrate 100A. The source and drain electrodes 150A are located on the underlying layer 110A and has an opening 152A formed therein. The oxide semiconductor layer 140A is located on a part of the underlying layer 110A that is a bottom part of the opening 152A and on the source and drain electrodes 150A. In other words, the oxide semiconductor layer 140A is located on the part of the underlying layer 110A exposed from the source and drain electrodes 150A and is connected with the source and drain electrodes 150A.

The gate insulating layer 130A is located on the oxide semiconductor layer 140A and the source and drain electrodes 150A. The gate electrode 120A is located to face the oxide semiconductor layer 140A with the gate insulating layer 130A being provided therebetween. As shown in FIG. 14, as seen in a plan view, the gate electrode 120A covers the oxide semiconductor layer 140A. Namely, the oxide semiconductor layer 140A is located inner to the gate electrode 120A.

As shown in FIG. 15 and FIG. 16, an underlying layer 110A-1 in an area where the source and drain electrodes 150A are not provided, namely, the underlying layer 110A-1 exposed from the source and drain electrodes 150A to contact the oxide semiconductor layer 140A, has a thickness smaller than that of an underlying layer 110A-2 located below the source and drain electrodes 150A.

The source and drain electrodes 150A include a pair of electrodes separated from each other with a distance. In accordance with the applied voltage, one of the pair of electrodes is the source electrode, and the other electrode is the drain electrode. The distance between the pair of electrodes corresponds to a channel length of the semiconductor device 10A.

The protective layer 160A covers the gate electrode 120A and the gate insulating layer 130A.

The substrate 100A, the underlying layer 110A, the gate electrode 120A, the gate insulating layer 130A, the oxide semiconductor layer 140A, the source and drain electrodes 150A, and the protective layer 160A may be formed of substantially the same materials as those of the semiconductor device 10 in embodiment 1.

### [Manufacturing Method of the Semiconductor Device 10A]

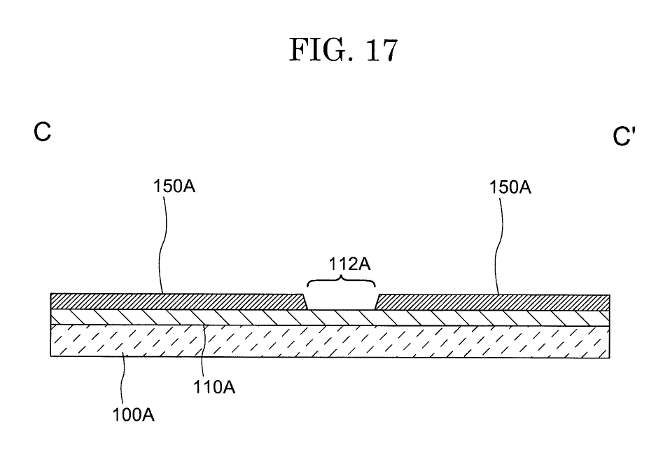

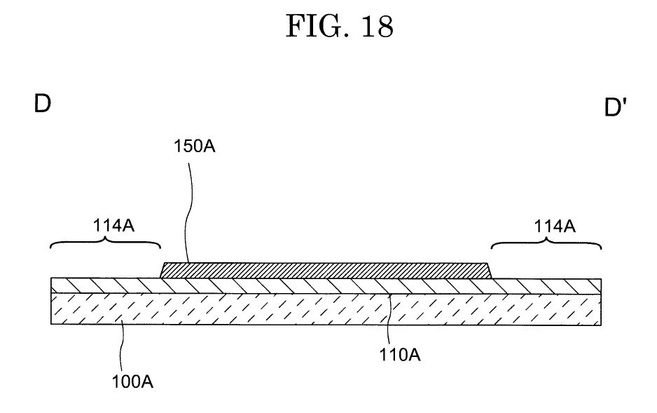

With reference to FIG. 17 through FIG. 26, a manufacturing method of the semiconductor device 10A in embodiment 2 according to the present invention will be described, FIG. 17 through FIG. 26 are each a cross-sectional view taken along line C-C′ or D-D′ in FIG. 14. FIG. 17 and FIG. 18 are respectively a cross-sectional view taken along line C-C′ and a cross-sectional view taken along line D-D′ showing a step of forming the source and drain electrodes 150A in the manufacturing method of the semiconductor device 10A in embodiment 2 according to the present invention. Referring to FIG. 17 and FIG. 18, the underlying layer 110A and a film for the source and drain electrodes 150A are formed on the substrate 100A, and patterning is performed by photolithography and etching to form the source and drain electrodes 150A shown in FIG. 14. Preferably, the etching for forming the source and drain electrodes 150A is performed under the condition that the etching rate ratio of the source and drain electrodes 150A with respect to the underlying layer 110A is high.

The etching for forming the source and drain electrodes 150A may be performed by use of chlorine-containing gas. As a result of the dry etching, the source and drain electrodes 150A are formed, and a part of the underlying 110A that is below the etched-away part of the film for the source and drain electrodes 150A is exposed. It is preferable to perform over-etching until the underlying layer 110A is exposed completely by the dry etching in order to suppress the etching for forming the source and drain electrodes 150A from being left partially undone.

Examples of the gas usable for the dry etching include Cl₂, BCl₃, CCl₄ and the like. These types of gas may be used independently or as a mixture thereof. For example, the dry etching may be performed by use of mixed gas of Cl₂ and BCl₃. The dry etching may be RIE, or a plasma process performed by use of any of the above-described types of gas.

With the dry etching, the underlying layer 110A formed of an inorganic insulating material such as, for example, SiOₓ, SiNₓ, SiOₓN_{y}, AlOₓ, AlNₓ, AlOₓN_{y}, AlNₓO_{y}, or the like is not etched almost at all. Namely, parts of the underlying layer 110A in regions 112A and 114A shown in FIG. 17 and FIG. 18 that are exposed from the source and drain electrodes 150A are not etched almost at all.

The parts of the underlying layer 110A that are in the regions 112A and 114A are exposed to a dry etching atmosphere. In other words, the parts of the underlying layer 110A that are in the regions 112A and 114A are exposed to plasma using chlorine-containing gas. Therefore, chlorine impurities are attached to a surface of the underlying layer 110A or implanted into the underlying layer 110A. The chlorine impurities are not limited to being generated by the dry etching performed to form the source and drain electrodes 150A, and may be generated by another type of plasma process performed by use of chlorine-containing gas.

When the chlorine impurities are reacted with water, hydrochloric acid is generated. When, for example, the substrate in FIG. 17 and FIG. 18 is washed, the chlorine impurities present in the parts of the underlying layer 110A that are in the regions 112A and 114A are reacted with water to generate hydrochloric acid. Also, the chlorine impurities are reacted with moisture contained in the oxide semiconductor layer 140A formed on the parts of the underlying layer 110A that are in the regions 112A and 114A in a later step, and as a result, hydrochloric acid is generated. Hydrochloric acid etches the oxide semiconductor layer 140A located on the regions 112A and 114A. Therefore, the chlorine impurities need to be removed in order to prevent the generation of hydrochloric acid.

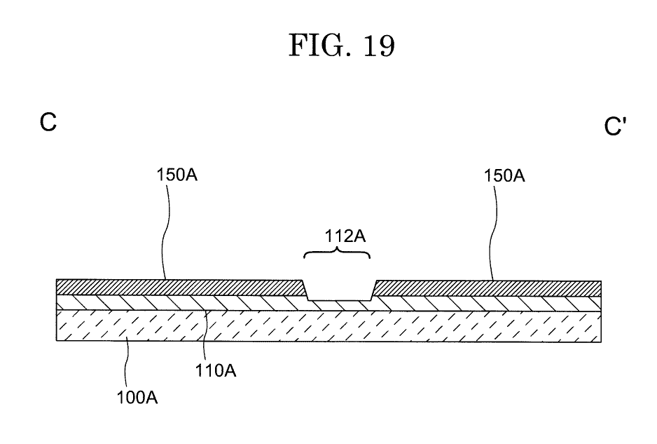

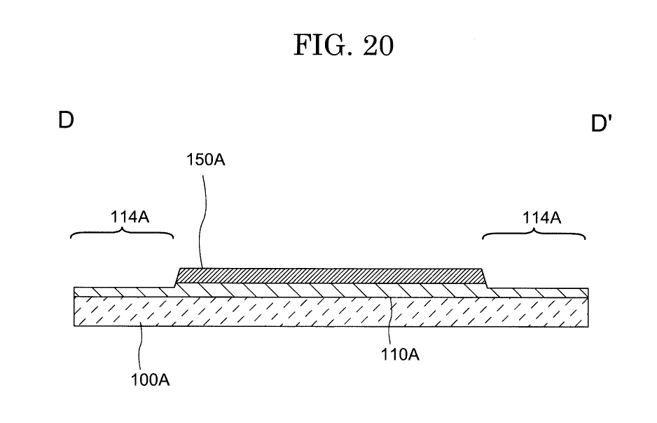

FIG. 19 and FIG. 20 are respectively a cross-sectional view taken along line C-C′ and a cross-sectional view taken along line D-D′ showing a step of performing a chlorine removal process of removing the chlorine impurities in the manufacturing method of the semiconductor device 10A in embodiment 2 according to the present invention. Referring to FIG. 19 and FIG. 20, the chlorine impurities present in the parts of the underlying layer 110A that are in the regions 112A and 114A are removed.

The chlorine removal process may be performed by dry etching by use of fluorine-containing gas. With the dry etching, the parts of the underlying layer 110A that are in the regions 112A and 114A, in which the chlorine impurities are present, namely, the parts of the underlying layer 110A exposed from the source and drain electrodes 150A are half-etched. The dry etching removes the chlorine impurities from the surface layer of the parts of the underlying layer 110A that are in the regions 112A and 114A. There is no specific limitation on the thickness of the half-etched part of the underlying layer 110A. The thickness of the half-etched parts of the underlying layer 110A may be greater than, or equal to, half of the thickness of the non-half-etched part of the underlying layer 110A, or may be less than, or equal to, half of the thickness of the non-half-etched part of the underlying layer 110A.

Examples of the gas usable for the dry etching for the chlorine removal process include CF₄, CHF₃, C₂F₆, SF₆ and the like. These types of gas may be used independently or as a mixture thereof. For example, the dry etching may be performed by use of mixed gas of CF₄ and CHF₃. The dry etching may be RIE, or a plasma process performed by use of any of the above-described types of gas.

The depth of the half-etching performed on the underlying layer 110A may be determined in accordance with the position of the chlorine impurities. In the case where, for example, the chlorine impurities are present in the surface layer of the underlying layer 110A, it is sufficient that the chlorine impurities are removed by the dry etching and the underlying layer 110A is etched even slightly. By contrast, in the case where chlorine atoms or chlorine ions are implanted into an area having a certain depth from the surface of the underlying layer 110A, it is preferable that the underlying layer 110A is etched to a level deeper than the area into which the chlorine atoms or the chlorine ions are implanted.

In the above example, the chlorine removal process is performed by dry etching by use of fluorine-containing gas. The method of the chlorine removal process is not limited to this. For example, the chlorine removal process may be performed by dry etching by use of another type of gas not containing chlorine. Instead of dry etching, plasma process, reverse sputtering or the like is usable for the chlorine removal process. Alternatively, the chlorine removal process may be performed by wet etching by use of a liquid chemical.

When the chlorine impurities are reacted with water, hydrochloric acid is generated. Therefore, the substrate may be kept in vacuum between the dry etching step for forming the source and drain electrodes 150A and the chlorine removal step. Keeping the substrate between these two steps suppresses hydrochloric acid from being generated due to moisture in the air.

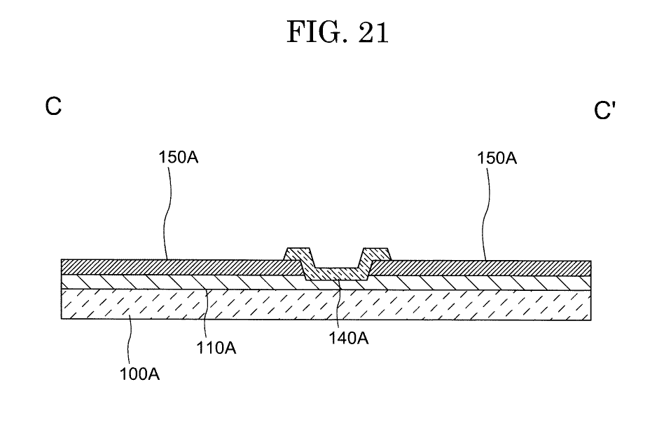

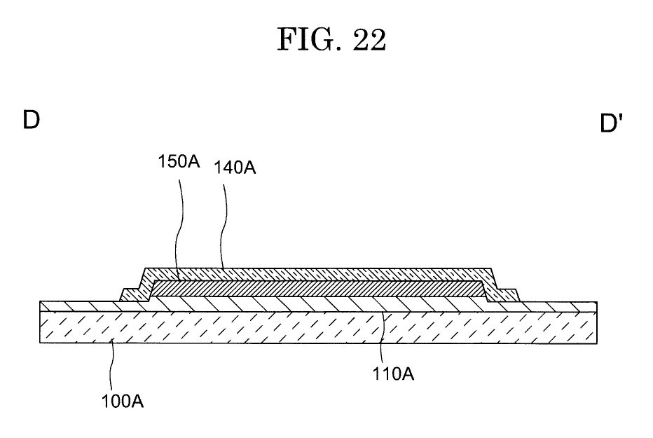

FIG. 21 and FIG. 22 are respectively a cross-sectional view taken along line C-C′ and a cross-sectional view taken along line D-D′ showing a step of forming the oxide semiconductor layer 140A in the manufacturing method of the semiconductor device 10A in embodiment 2 according to the present invention. Referring to FIG. 21 and FIG. 22, a film for the oxide semiconductor layer 140A is formed on the underlying layer 110A and the source and drain electrodes 150A, and patterning is performed by photolithography and etching to form the oxide semiconductor layer 140A shown in FIG. 14.

The oxide semiconductor layer 140A may be formed by sputtering. The etching performed to form the oxide semiconductor layer 140A may be dry etching or wet etching. In the case where the oxide semiconductor layer 140A is formed by wet etching, an etchant containing oxalic acid, an etchant containing phosphoric acid, or an etchant containing hydrogen fluoride may be used.

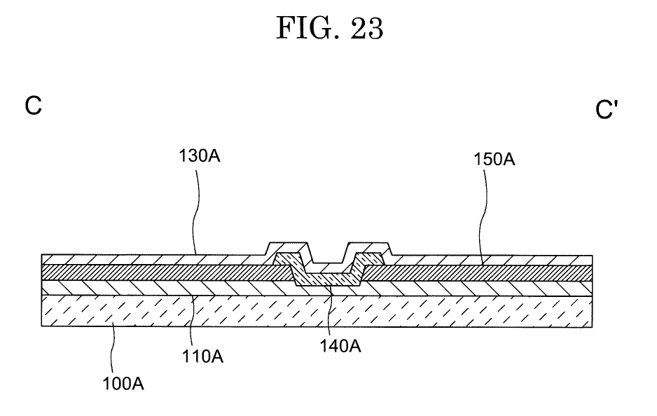

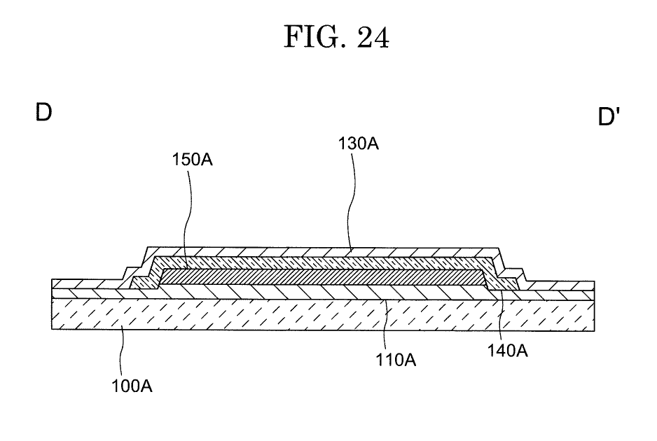

FIG. 23 and FIG. 24 are respectively a cross-sectional view taken along line C-C′ and a cross-sectional view taken along line D-D′ showing a step of forming the gate insulating layer 130A in the manufacturing method of the semiconductor device 10A in embodiment 2 according to the present invention. Referring to FIG. 23 and FIG. 24, the gate insulating layer 130A is formed on the source and drain electrodes 150A and the oxide semiconductor layer 140A. When necessary, an opening may be formed in the gate insulating layer 130A.

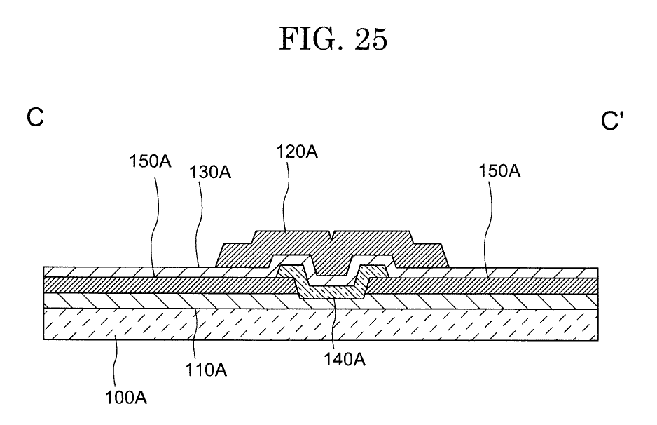

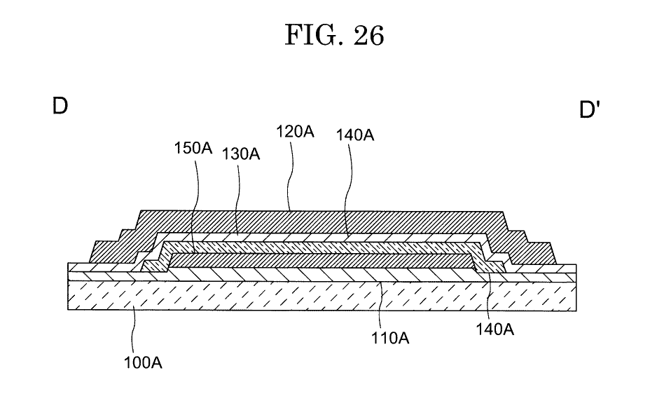

FIG. 25 and FIG. 26 are respectively a cross-sectional view taken along line C-C′ and a cross-sectional view taken along line D-D′ showing a step of forming the gate electrode 120A in the manufacturing method of the semiconductor device 10A in embodiment 2 according to the present invention. Referring to FIG. 25 and FIG. 26, a film for the gate electrode 120A is formed on gate insulating layer 130A, and patterning is performed by photolithography and etching to form the gate electrode 120A shown in FIG. 14. Preferably, the etching for forming the gate electrode 120A is performed under the condition that the etching rate ratio of the gate electrode 120A with respect to the gate insulating layer 130A is high.

The protective layer 160A is formed on the entirety of a surface of the substrate shown in FIG. 25 and FIG. 26. With the above-described manufacturing method, the semiconductor device 10A in embodiment 2 according to the present invention is manufactured.

As described above, with the manufacturing method of the semiconductor device 10A in embodiment 2 according to the present invention, the chlorine impurities generated in the surface layer of the underlying layer 110A by the plasma process performed by use of chlorine-containing gas are removed. Therefore, generation of chlorine is suppressed in later steps, and thus the oxide semiconductor layer 140A is suppressed from being etched. The semiconductor device 10A manufactured by such a method is highly reliable.

### Embodiment 3

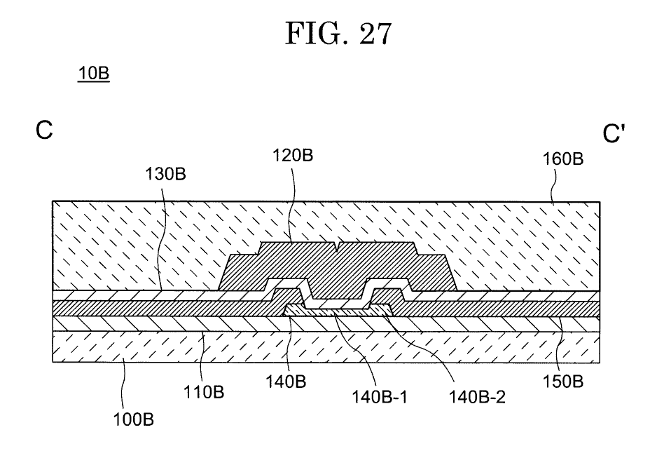

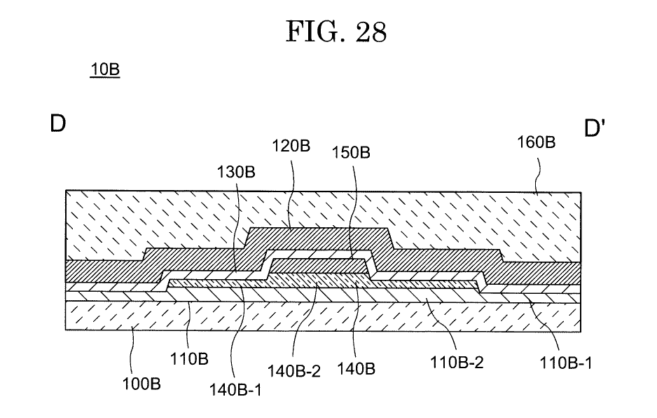

With reference to FIG. 27 and FIG. 28, an overview of a semiconductor device 10B in embodiment 3 according to the present invention will be described. The semiconductor device 10B in embodiment 3 is usable in a pixel or a driving circuit of a liquid crystal display device (LCD), a spontaneous emission display device using an organic light-emitting diode (OLED) such as an organic EL element, a quantum dot or the like for a display unit, or a reflection-type display device such as an electronic paper or the like.

### [Structure of the Semiconductor Device 10B]

A plan view of the semiconductor device 10B is the same as that of the semiconductor device 10A in embodiment 2 (shown in FIG. 14), and FIG. 14 is referred to for the description. FIG. 27 is a cross-sectional view showing an overview of the semiconductor device 10B in embodiment 3 according to the present invention, taken along line C-C′ in FIG. 14. FIG. 28 is a cross-sectional view showing an overview of the semiconductor device 10B in embodiment 3 according to the present invention, taken along line D-D′ in FIG. 14. As shown in FIG. 27 and FIG. 28, the semiconductor device 10B includes a substrate 100B, an underlying layer 110B, an oxide semiconductor layer 140B, source and drain electrodes 150B, a gate insulating layer 130B, a gate electrode 120B, and a protective layer 160B. The semiconductor device 10B is a top gate-type transistor.

The underlying layer 110B is located on the substrate 100B. The oxide semiconductor layer 140B is located on the underlying layer 110B. The source and drain electrodes 150B are located on the underlying layer 110B and the oxide semiconductor layer 140B and patterned to expose a part of the oxide semiconductor layer 140B. An underlying layer 110B-1 exposed from the oxide semiconductor layer 140B has a thickness smaller than that of an underlying layer 110B-2 located below the oxide semiconductor layer 140B or the source and drain electrodes 150B. An oxide semiconductor layer 140B-1 exposed from the source and drain electrodes 150B has a thickness smaller than that of an oxide semiconductor layer 140B-2 located below the source and drain electrodes 150B.

The gate insulating layer 130B is located on the oxide semiconductor layer 140B and the source and drain electrodes 150B. The gate electrode 120B is located to face the oxide semiconductor layer 140B with the gate insulating layer 130B being provided therebetween. Like in FIG. 14, as seen in a plan view, the gate electrode 120B is located to cover the oxide semiconductor layer 140B. Namely, the oxide semiconductor layer 140B is located inner to the gate electrode 120B.

The source and drain electrodes 150B include a pair of electrodes separated from each other with a distance. In accordance with the applied voltage, one of the pair of electrodes is the source electrode, and the other electrode is the drain electrode. The distance between the pair of electrodes corresponds to a channel length of the semiconductor device 10B.

The protective layer 160B covers the gate electrode 120B and the gate insulating layer 130B.

The substrate 100B, the underlying layer 110B, the gate electrode 120B, the gate insulating layer 130B, the oxide semiconductor layer 140B, the source and drain electrodes 150B, and the protective layer 160B may be formed of substantially the same materials as those of the semiconductor device 10 in embodiment 1.

### [Manufacturing Method of the Semiconductor Device 10B]

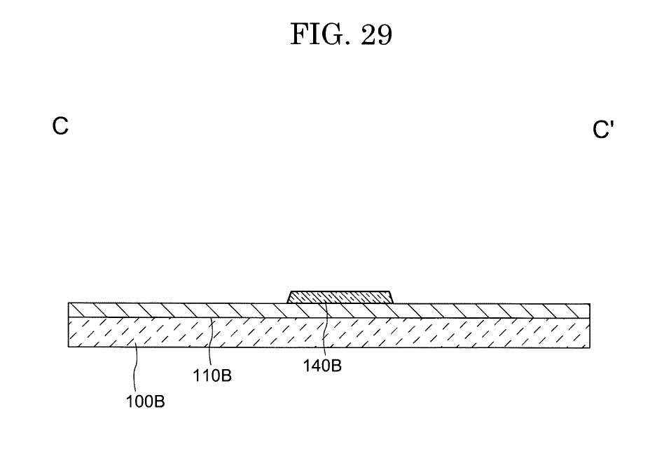

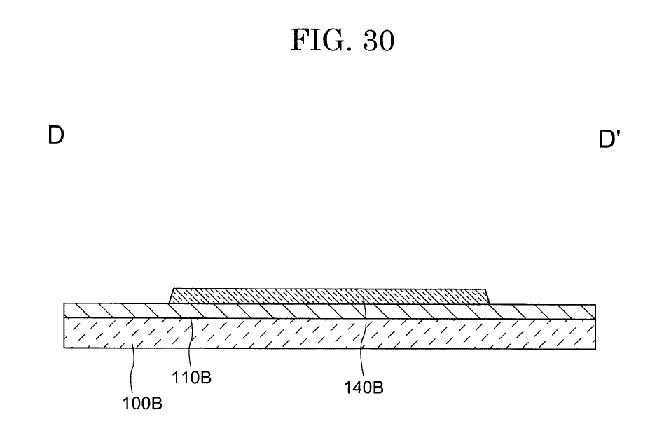

With reference to FIG. 29 through FIG. 38, a manufacturing method of the semiconductor device 10B in embodiment 3 according to the present invention will be described, FIG. 29 through FIG. 38 are each a cross-sectional view taken along line C-C′ or D-D′ in FIG. 14. FIG. 29 and FIG. 30 are respectively a cross-sectional view taken along line C-C′ and a cross-sectional view taken along line D-D′ showing a step of forming the oxide semiconductor layer 140B in the manufacturing method of the semiconductor device 10B in embodiment 3 according to the present invention. Referring to FIG. 29 and FIG. 30, the underlying layer 110B and a film for the oxide semiconductor layer 140B are formed on the substrate 100B, and patterning is performed by photolithography and etching to form the oxide semiconductor layer 140B like in FIG. 14.

The oxide semiconductor layer 140B may be formed by sputtering. The etching performed to form the oxide semiconductor layer 140B may be dry etching or wet etching. In the case where the oxide semiconductor layer 140B is formed by wet etching, an etchant containing oxalic acid, an etchant containing phosphoric acid, or an etchant containing hydrogen fluoride may be used.

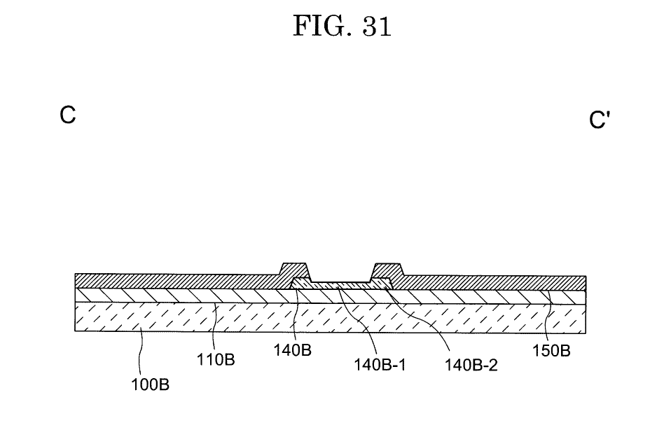

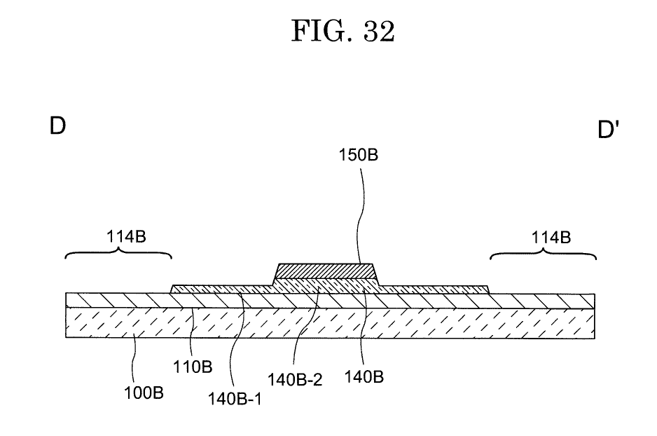

FIG. 31 and FIG. 32 are respectively a cross-sectional view taken along line C-C′ and a cross-sectional view taken along line D-D′ showing a step of forming the source and drain electrodes 150B in the manufacturing method of the semiconductor device 10B in embodiment 3 according to the present invention. Referring to FIG. 31 and FIG. 32, a film for the source and drain electrodes 150B is formed on the underlying layer 110B and the oxide semiconductor layer 140B, and patterning is performed by photolithography and etching to form the source and drain electrodes 150B like in FIG. 14.

The etching for forming the source and drain electrodes 150B may be performed by use of chlorine-containing gas. As a result of the dry etching, the source and drain electrodes 150B are formed, and a part of the oxide semiconductor layer 140B and a part of the underlying 110B that are below the etched-away part of the film for the source and drain electrodes 150B are exposed. The part of the oxide semiconductor layer 140B that is exposed by the dry etching is half-etched in order to suppress the etching for forming the source and drain electrodes 150B from being left partially undone. Namely, the oxide semiconductor layer 140B is etched so that the thickness of the oxide semiconductor layer 140B-1 exposed from the source and drain electrodes 150B is smaller than that of the oxide semiconductor layer 140B-2 located below the source and drain electrodes 150B. There is no specific limitation on the thickness of the half-etched part of the oxide semiconductor layer 140B. The thickness of the half-etched part of the oxide semiconductor layer 140B may be greater than, or equal to, half of the thickness of the non-half-etched part of the oxide semiconductor layer 140B, or may be less than, or equal to, half of the thickness of the non-half-etched part of the oxide semiconductor layer 140B.

Examples of the gas usable for the dry etching include Cl₂, BCl₃, CCl₄ and the like. These types of gas may be used independently or as a mixture thereof. For example, the dry etching may be performed by use of mixed gas of Cl₂ and BCl₃. The dry etching may be RIE, or a plasma process performed by use of any of the above-described types of gas.

With the dry etching, the underlying layer 110B formed of an inorganic insulating material such as, for example, SiOₓ, SiNₓ, SiOₓN_{y}, SiNₓO_{y}, AlOₓ, AlNₓ, AlOₓN_{y}, AlNₓO_{y}, or the like is not etched almost at all. Namely, a part of the underlying layer 110B in a region 114B shown in FIG. 32 that is exposed from the source and drain electrodes 150B and the oxide semiconductor layer 140B is not etched almost at all.

The part of the underlying layer 110B that is in the region 114B is exposed to a dry etching atmosphere. In other words, the part of the underlying layer 110B that is in the region 114B is exposed to plasma using chlorine-containing gas. Therefore, chlorine impurities are attached to a surface of the underlying layer 110B or implanted into the underlying layer 110B. The chlorine impurities are not limited to being generated by the dry etching performed to form the source and drain electrodes 150B, and may be generated by another type of plasma process performed by use of chlorine-containing gas.

When the chlorine impurities are reacted with water, hydrochloric acid is generated. When, for example, the substrate in FIG. 31 and FIG. 32 is washed, the chlorine impurities present in the part of the underlying layer 110B that is in the region 114B are reacted with water to generate hydrochloric acid. Also, the chlorine impurities are reacted with moisture contained in the oxide semiconductor layer 140B formed on the part of the underlying layer 110B that is in the region 114B in a later step, and as a result, hydrochloric acid is generated. Hydrochloric acid etches the oxide semiconductor layer 140B located on the region 114B. Therefore, the chlorine impurities need to be removed in order to prevent the generation of hydrochloric acid.

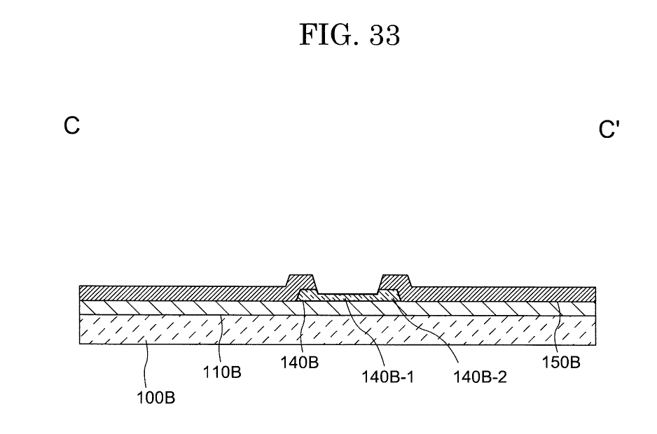

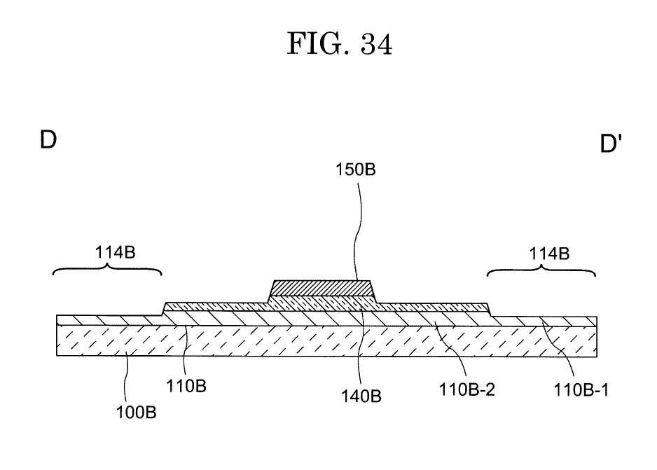

FIG. 33 and FIG. 34 are respectively a cross-sectional view taken along line C-C′ and a cross-sectional view taken along line D-D′ showing a step of performing a chlorine removal process of removing the chlorine impurities in the manufacturing method of the semiconductor device 10B in embodiment 3 according to the present invention. Referring to FIG. 33 and FIG. 34, the chlorine impurities present in the part of the underlying layer 110B that is in the region 114B are removed.

The chlorine removal process may be performed by dry etching by use of fluorine-containing gas. With the dry etching, the part of the underlying layer 110B that is in the region 114B, in which the chlorine impurities are present, namely, the part of the underlying layer 110B exposed from the source and drain electrodes 150B and the oxide semiconductor layer 140B is half-etched. The dry etching removes the chlorine impurities from the surface layer of the part of the underlying layer 110B that is in the region 114B. There is no specific limitation on the thickness of the half-etched underlying layer 110B-1. The thickness of the half-etched underlying layer 110B-1 may be greater than, or equal to, half of the thickness of the non-half-etched underlying layer 110B-2, or may be less than, or equal to, half of the thickness of the non-half-etched underlying layer 110B-2.

Examples of the gas usable for the dry etching for the chlorine removal process include CF₄, CHF₃, C₂F₆, SF₆ and the like. These types of gas may be used independently or as a mixture thereof. For example, the dry etching may be performed by use of mixed gas of CF₄ and CHF₃. The dry etching may be RIE, or a plasma process performed by use of any of the above-described types of gas.

The depth of the half-etching performed on the underlying layer 110B may be determined in accordance with the position of the chlorine impurities. In the case where, for example, the chlorine impurities are present in the surface layer of the underlying layer 110B, it is sufficient that the chlorine impurities are removed by the dry etching and the underlying layer 110B is etched even slightly. By contrast, in the case where chlorine atoms or chlorine ions are implanted into an area having a certain depth from the surface of the underlying layer 110B, it is preferable that the underlying layer 110B is etched to a level deeper than the area into which the chlorine atoms or the chlorine ions are implanted.

In the above example, the chlorine removal process is performed by dry etching by use of fluorine-containing gas. The method of the chlorine removal process is not limited to this. For example, the chlorine removal process may be performed by dry etching by use of another type of gas not containing chlorine. Instead of dry etching, plasma process, reverse sputtering or the like is usable for the chlorine removal process. Alternatively, the chlorine removal process may be performed by wet etching by use of a liquid chemical.

When the chlorine impurities are reacted with water, hydrochloric acid is generated. Therefore, the substrate may be kept in vacuum between the dry etching step for forming the source and drain electrodes 150B and the chlorine removal step. Keeping the substrate between these two steps suppresses hydrochloric acid from being generated due to moisture in the air.

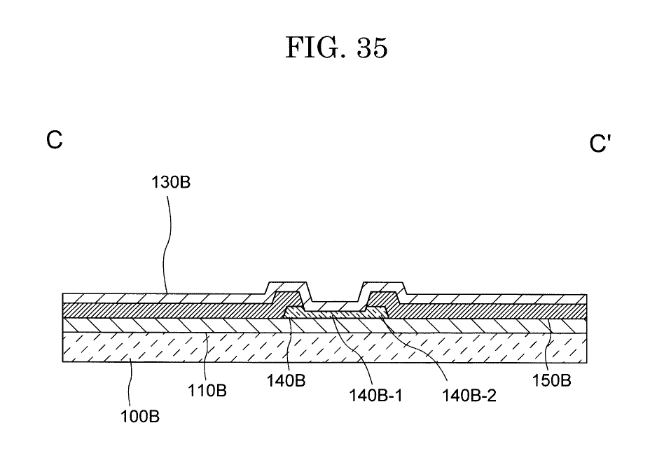

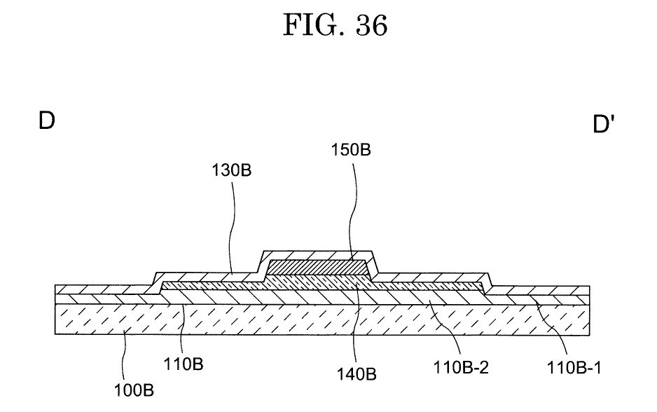

FIG. 35 and FIG. 36 are respectively a cross-sectional view taken along line C-C′ and a cross-sectional view taken along line D-D′ showing a step of forming the gate insulating layer 130B in the manufacturing method of the semiconductor device 10B in embodiment 3 according to the present invention. Referring to FIG. 35 and FIG. 36, the gate insulating layer 130B is formed on the source and drain electrodes 150B and the oxide semiconductor layer 140B. An opening may be formed in the gate insulating layer 130B.

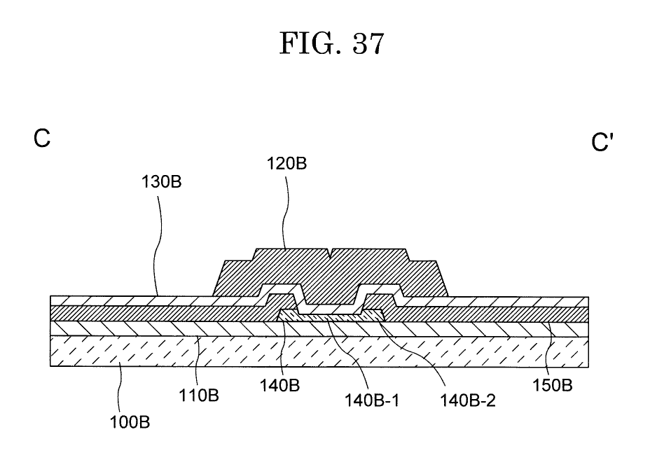

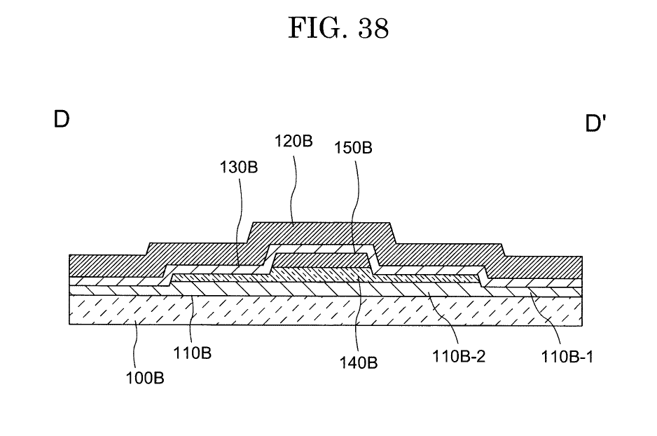

FIG. 37 and FIG. 38 are respectively a cross-sectional view taken along line C-C′ and a cross-sectional view taken along line D-D′ showing a step of forming the gate electrode 120B in the manufacturing method of the semiconductor device 10B in embodiment 3 according to the present invention. Referring to FIG. 37 and FIG. 38, a film for the gate electrode 120B is formed on gate insulating layer 130B, and patterning is performed by photolithography and etching to form the gate electrode 120B like in FIG. 14. Preferably, the etching for forming the gate electrode 120B is performed under the condition that the etching rate ratio of the gate electrode 120B with respect to the gate insulating layer 130B is high.

The protective layer 160B is formed on the entirety of a surface of the substrate shown in FIG. 37 and FIG. 38. With the above-described manufacturing method, the semiconductor device 10B in embodiment 3 according to the present invention is manufactured.

As described above, with the manufacturing method of the semiconductor device 10B in embodiment 3 according to the present invention, the chlorine impurities generated in the surface layer of the underlying layer 110B by the plasma process performed by use of chlorine-containing gas are removed. Therefore, generation of chlorine is suppressed in later steps, and thus the oxide semiconductor layer 140B is suppressed from being etched. The semiconductor device 10B manufactured by such a method is highly reliable.

### EXAMPLES

Semiconductor devices in embodiment 1 and embodiment 2 (examples) according to the present invention and semiconductor devices in a comparative example were manufactured. The following evaluations were performed on these semiconductor devices: impurity evaluation on the insulating layer to which the chlorine impurities were attached or implanted, transistor characteristic fluctuation evaluation performed by directing light toward the semiconductor devices, and evaluation with optical microscope. Hereinafter, the results of these evaluations will be described.

### [Impurity Evaluation]

Test samples were manufactured to reproduce the state of the part of the gate insulating layer 130 in the region 132 in embodiment 1 (see FIG. 11) and the state of the parts of the underlying layer 110A in the regions 112A and 114A in embodiment 2 (see FIG. 17 and FIG. 18). On the test samples, an impurity evaluation was performed in the depth direction by time-of-flight secondary ion mass spectrometry (ToF-SIMS).

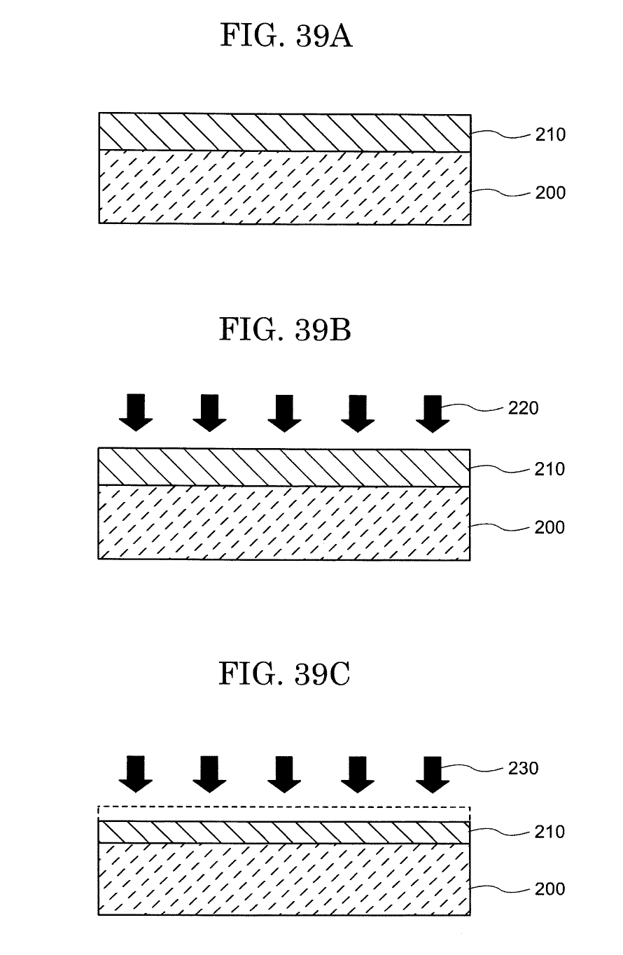

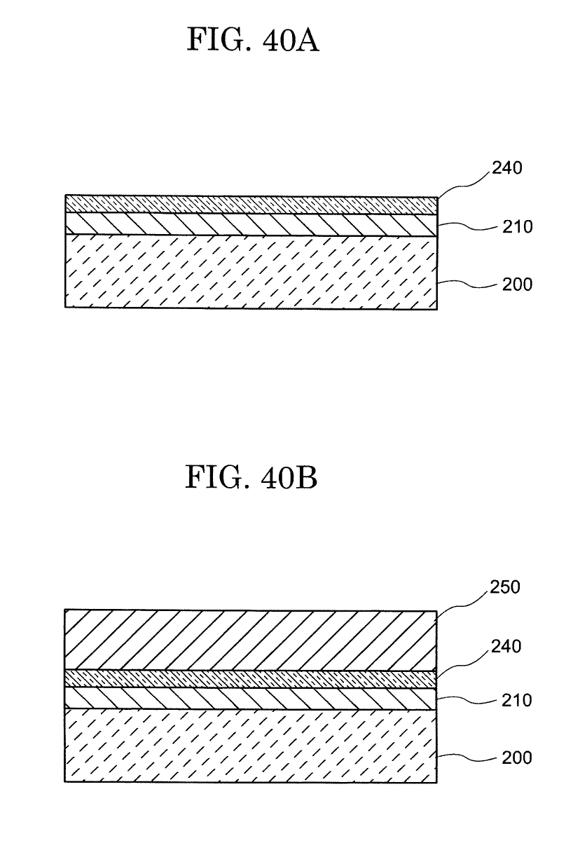

FIG. 39A, FIG. 39B, FIG. 39C, FIG. 40A and FIG. 40B show a manufacturing method of example test samples and comparative example test samples. First, as shown in FIG. 39A, an insulating layer 210 formed of SiOₓ corresponding to the underlying layer was formed to a thickness of about 500 nm on a silicon substrate 200. Next, as shown in FIG. 39B, a surface of the insulating layer 210 was subjected to dry etching by use of mixed gas of Cl₂ and BCl₃ as an example of the chlorine-containing gas (chlorine etching 220). The insulating layer 210 was not etched almost at all by the chlorine etching 220. Next, as shown in FIG. 390, the insulating layer 210 having the chlorine impurities implanted thereto was subjected to dry etching by use of mixed gas of CF₄, CHF₃ and Ar as an example of the fluorine-containing gas (fluorine etching 230). The insulating layer 210 was etched by about 50 nm by the fluorine etching 230.

The chlorine etching 220 and the fluorine etching 230 were performed under the following conditions.

### [Conditions for the Chlorine Etching 220]

Etching system: ECR (Electron Cyclotron Resonance) system
Process gas: Cl₂/BCl₃=90/60 sccm
Chamber pressure: 20 mTorr
Chamber temperature: 40° C.
Bias power: 50 W
Current value: 400 mA

### [Conditions for the Fluorine Etching 230]

Etching system: Parallel plate system
Process gas: CF₄/CHF₃/Ar=60/20/300 sccm
Chamber pressure: 2 Torr
Chamber temperature: 25° C.
RF power: 200 W
Inter-electrode gap: 10 mm

The example samples were subjected to the fluorine etching 230, whereas the comparative example samples were not subjected to the fluorine etching 230. Namely, the difference between the example samples and the comparative example samples was whether the fluorine etching 230 was performed or not.

Next, as shown in FIG. 40A, an oxide semiconductor layer 240 formed of IGZO was formed by sputtering to a thickness of about 80 nm on the insulating layer 210. As IGZO, an IGZO target having a composition ratio of In:Ga:Zn:O=1:1:1:4 was used. Next, as shown in FIG. 40B, a protective layer 250 formed of SiOₓ was formed to a thickness of about 200 nm on the oxide semiconductor layer 240. The samples having a structure shown in FIG. 40B were analyzed by ToF-SIMS from above the samples (from the side on which the protective layer 250 was formed)

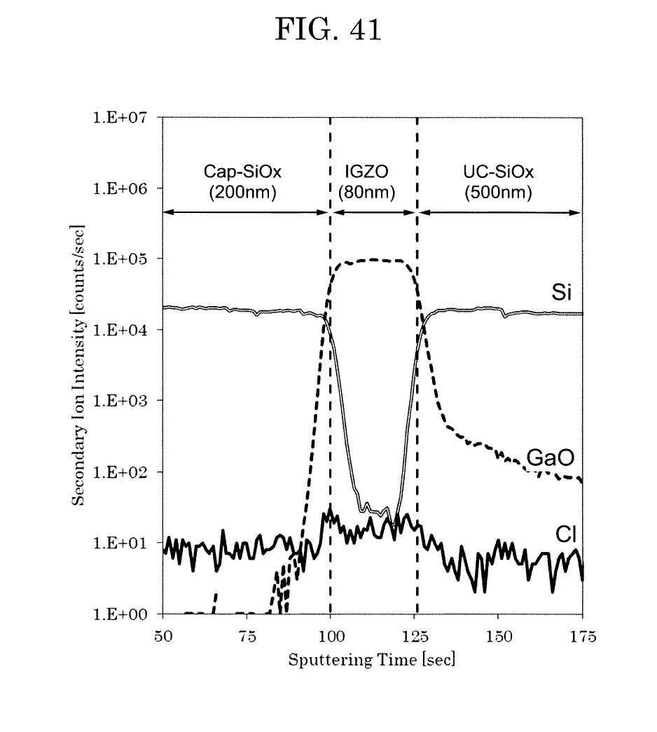

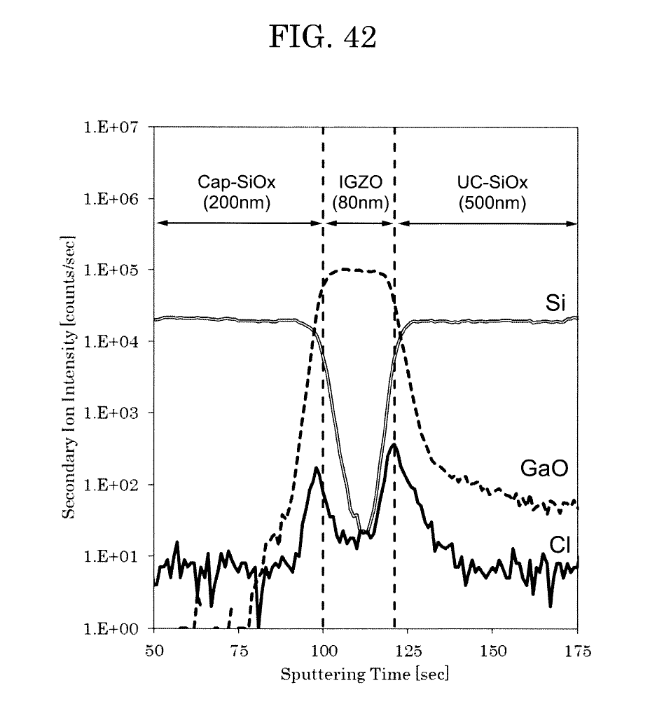

FIG. 41 and FIG. 42 respectively show the results of the ToF-SIMS analysis performed on the example samples according to the present invention and on the comparative example samples. In FIG. 41 and FIG. 42, the insulating layer 210 is expressed as US-SiOₓ, the oxide semiconductor layer 240 is expressed as IGZO, and the protective layer 250 is expressed as Cap-SiOₓ. The solid line represents the chlorine concentration (Cl concentration), the dotted line represents the gallium oxide concentration (GaO concentration), and the white line represents the silicon concentration (Si concentration). As shown in FIG. 41, regarding the example samples, it has been confirmed that the Cl concentration profile in the UC-SiOₓ film, the IGZO film and the Cap-SiOₓ film and at an interface between these thin films does not exhibit any specific concentration gradient and is generally constant.

By contrast, as shown in FIG. 42, regarding the comparative example samples, it has been confirmed that the Cl concentration profile is higher at and in the vicinity of the interface between the UC-SiOₓ film and the IGZO film and at and in the vicinity of the interface between the IGZO film and the Cap-SiOₓ film than in each of these thin films. It has also been confirmed that the Cl concentration in the comparative example samples at both of the interfaces is higher by one digit than the Cl concentration in the example samples. Namely, in the comparative example samples, the chlorine impurities implanted into the surface layer of the US-SiOₓ film by the chlorine etching 220 were not removed and were piled up at the interfaces between the thin films. By contrast, in the example samples, the chlorine impurities implanted into the surface layer of the US-SiOₓ film were removed by the fluorine etching 230.

It is considered that the chlorine impurities were piled up at and in the vicinity of the interface between IGZO and Cap-SiOₓ because the chlorine impurities present at and in the vicinity of the interface between UC-SiOₓ and IGZO were diffused by heat generated by the film formation of Cap-SiOₓ and trapped at and in the vicinity of the interface between IGZO and Cap-SiOₓ.

Based on the results, it is considered that the chlorine impurities are diffused by heat and piled up at the interfaces between the thin films.

### [Transistor Characteristic Fluctuation Evaluation]

Semiconductor devices 10 in embodiment 1 (example) according to the present invention and semiconductor devices in a comparative example were manufactured. These semiconductor devices were evaluated on the transistor characteristics when being irradiated with light and the transistor characteristics when not being irradiated with light. The semiconductor devices in the comparative example were manufactured by the manufacturing method of the semiconductor device 10 except that the chlorine removal step was not performed.

The channel length (L) and the channel width (W) of the manufactured semiconductor devices were L/W =6.0/6.0 μm. Namely, referring to FIG. 1, the distance between the pair of electrodes as the source and drain electrodes 150, and the width of each of the source and drain electrodes 150, were both 6.0 μm, For evaluating the transistor characteristics, the drain voltage VD was fixed to 10 V and the gate voltage VG was varied from −20 V to +20 V to measure the drain current ID, thus to find the ID-VG characteristic. The temperature at the time of the transistor characteristic evaluation was 85° C. The transistor characteristic evaluation was performed in a dark room, and the part of the oxide semiconductor layer 140 exposed from the source and drain electrodes 150 was irradiated with light directed from above, namely, from the side of the protective layer 160. The irradiation light was white LED light of 7000 lx.

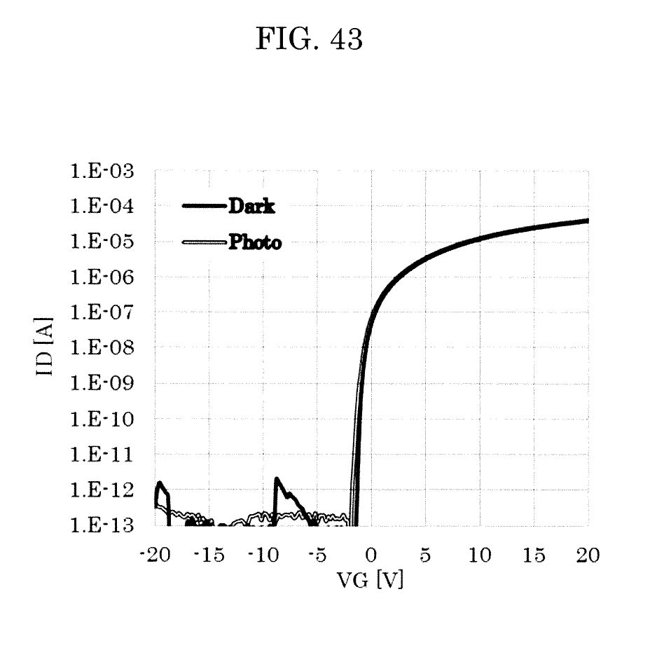

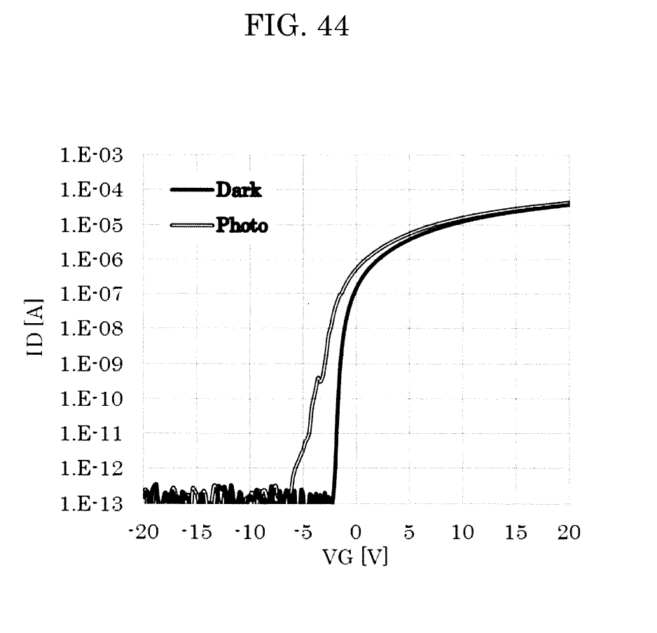

FIG. 43 and FIG. 44 respectively show the results of the transistor reliability test performed on the example samples and on the comparative example samples. In FIG. 43 and FIG. 44, the solid line represents the transistor characteristic evaluated without irradiation with light (Dark characteristic), and the white line represents the transistor characteristic evaluated with irradiation with light (Photo characteristic). As shown in FIG. 43, regarding the example samples, there is almost no difference between the Dark characteristic and the Photo characteristic. By contrast, as shown in FIG. 44, regarding the comparative example samples, as compared with the Dark characteristic, the Photo characteristic is shifted to the minus side of the gate voltage VG at the rise of the drain current ID, and the rise of the drain current ID is milder. Namely, it is considered that in the comparative example samples, a defect is generated in the oxide semiconductor layer acting as the channel, whereas in the example samples, generation of the defect in the oxide semiconductor layer acting as the channel is suppressed.

[Evaluation with Optical Microscope]

Semiconductor devices 10A in embodiment 2 (example) according to the present invention and semiconductor devices in a comparative example were manufactured. These semiconductor devices were evaluated on the shape thereof by an optical microscope. The semiconductor devices in the comparative example were manufactured by the manufacturing method of the semiconductor device 10A except that the chlorine removal step was not performed.

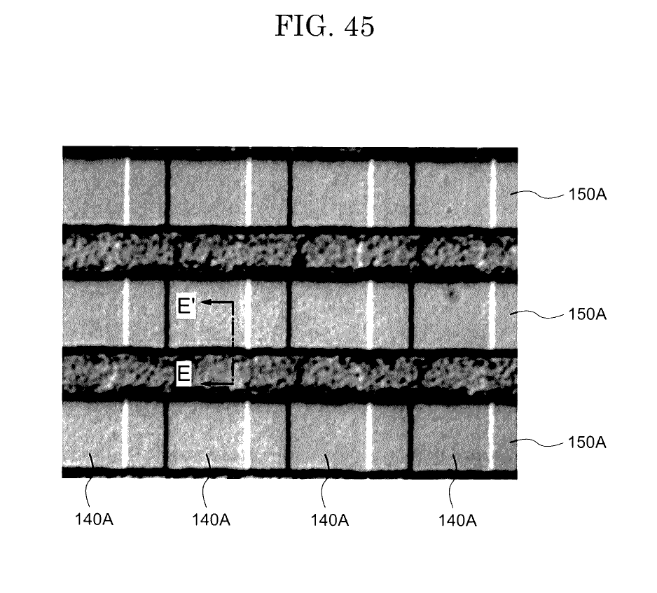

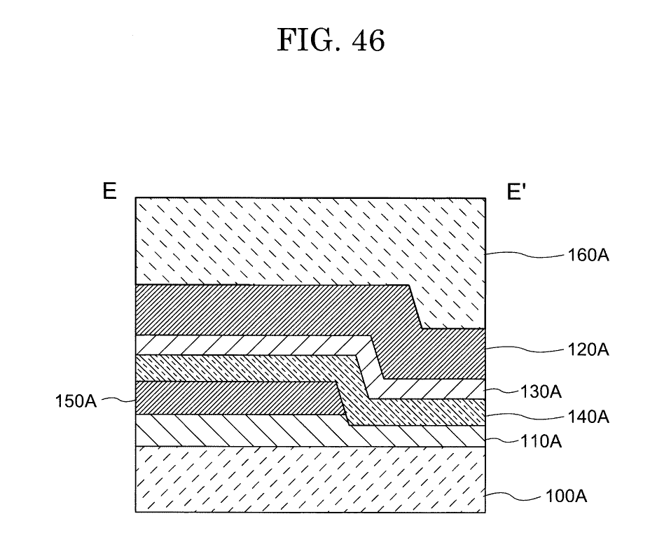

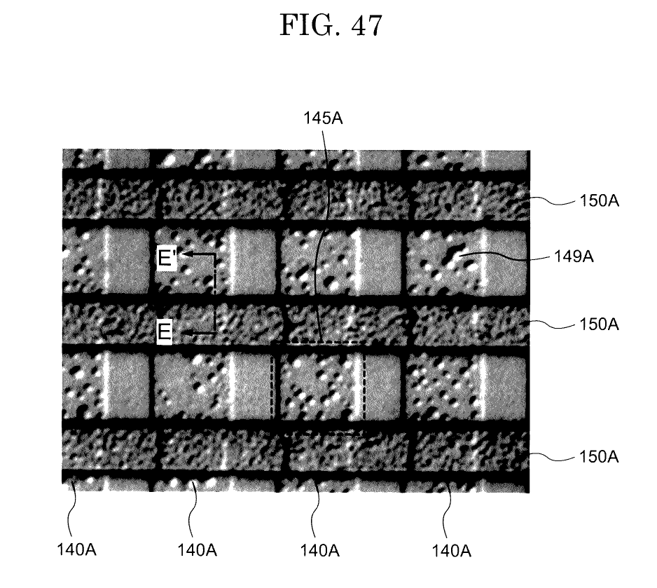

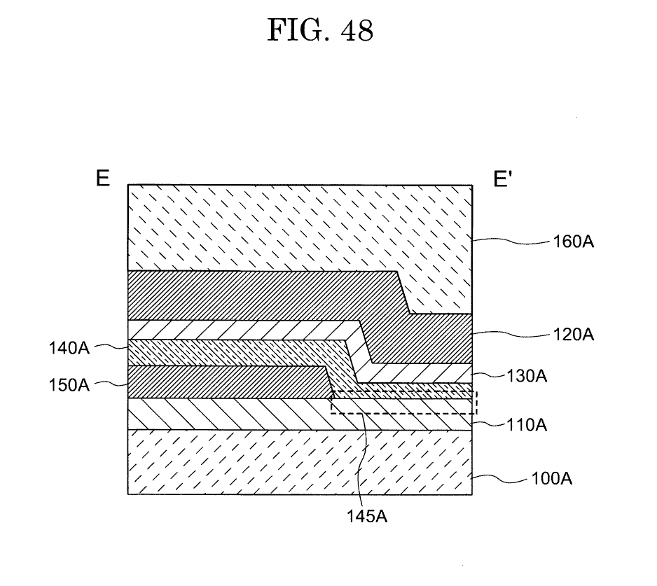

FIG. 45 shows an optical micrograph of a transistor as an example sample according to the present invention. FIG. 46 is a schematic cross-sectional view of FIG. 45 taken along line E-E′ in FIG. 45, FIG. 47 shows an optical micrograph of a transistor as a comparative example sample. FIG. 48 is a schematic cross-sectional view of FIG. 47 taken along line E-E′ in FIG. 47.

The example sample shown in FIG. 45 and the comparative example sample shown in FIG. 47 are compared. In the example sample, no specific shape abnormality is found in the oxide semiconductor layer 140. By contrast, in the comparative example sample, a shape abnormality is found in a region 145A (FIG. 48) where the underlying layer 110A and the oxide semiconductor layer 140A are in contact with each other. More specifically, in the comparative example, spots 149A are found in the region 145A. The spots 149A are considered to be formed because the oxide semiconductor layer 140A was etched, resulting in formation of a cavity in the region 145A shown in FIG. 48.

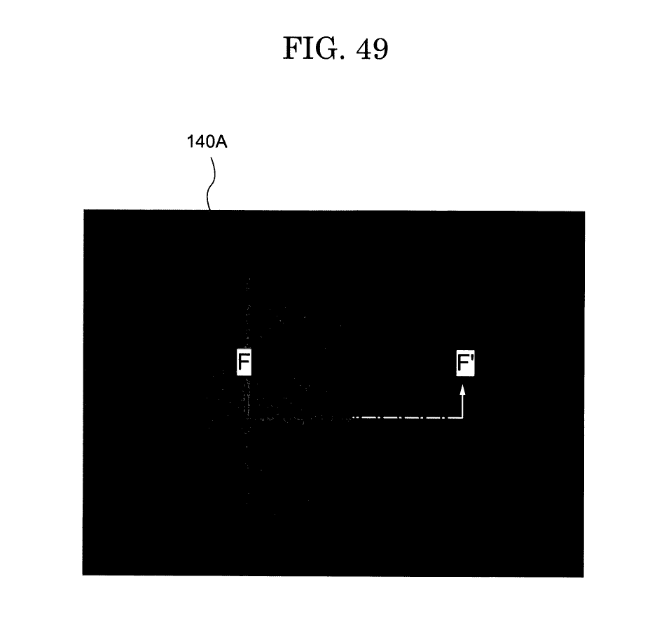

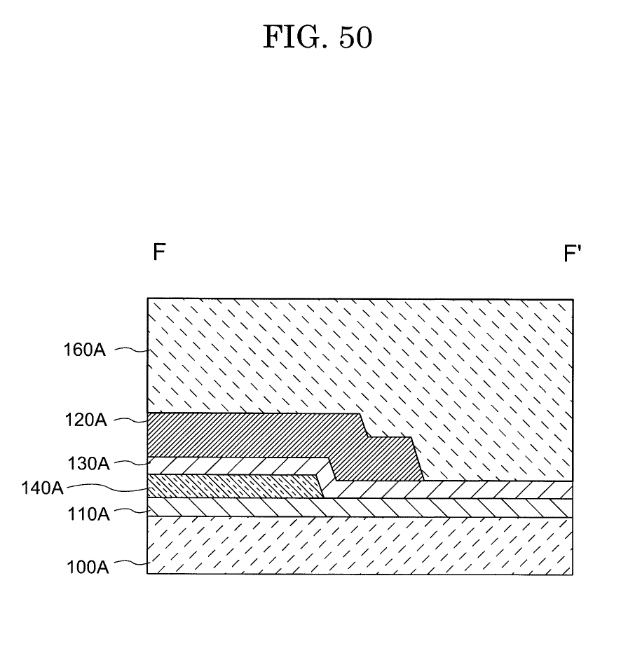

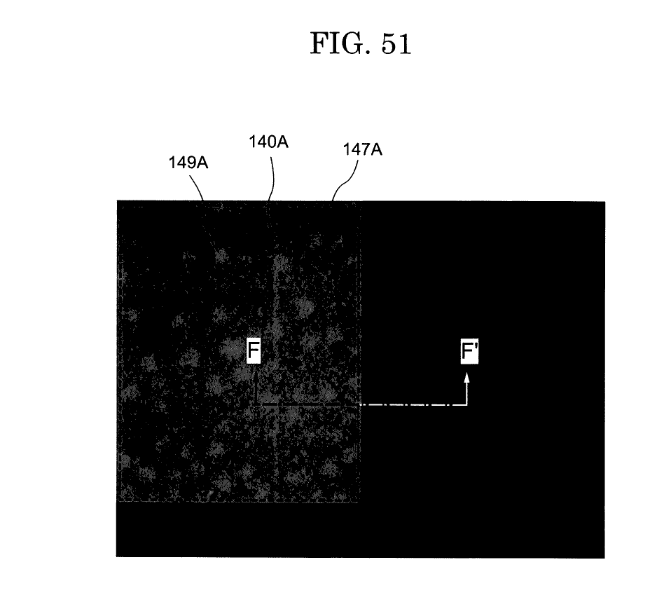

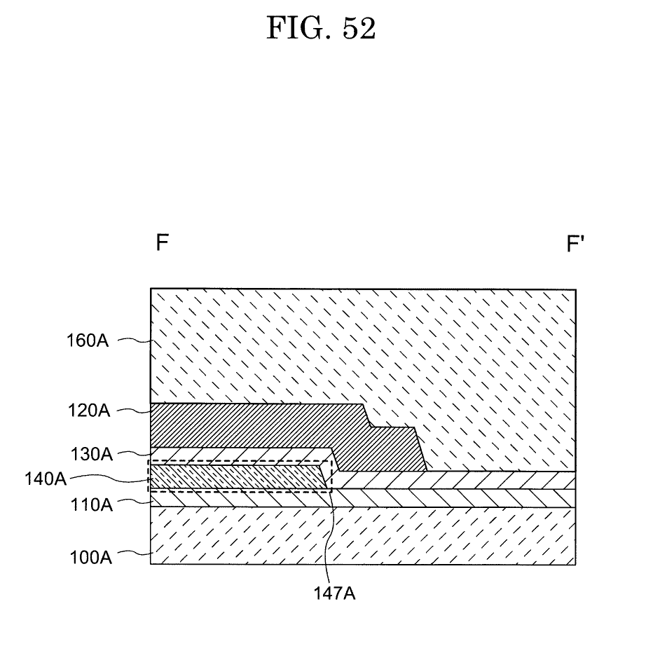

FIG. 49 shows an optical micrograph of a transistor as an example sample according to the present invention. FIG. 50 is a schematic cross-sectional view of FIG. 49 taken along line F-F′ in FIG. 49. FIG. 51 shows an optical micrograph of a transistor as a comparative example sample. FIG. 52 is a schematic cross-sectional view of FIG. 51 taken along line F-F′ in FIG. 51.

The example sample shown in FIG. 49 and the comparative example sample shown in FIG. 51 are compared. In the example sample, no specific shape abnormality is found in the oxide semiconductor layer 140. By contrast, in the comparative example sample, a shape abnormality is found in a region 147A (FIG. 52) where the underlying layer 110A and the oxide semiconductor layer 140A are in contact with each other, and the oxide semiconductor layer 140A and the gate insulating layer 130A are in contact with each other. More specifically, in the comparative example, spots 149A are found in the region 147A. The spots 149A are considered to be formed because the oxide semiconductor layer 140A was etched, resulting in formation of a cavity in the region 147A shown in FIG. 52.

From the above-described results, it has been confirmed that in the examples, the chlorine impurities are not piled up at the interfaces between the thin films, the transistor characteristics are fluctuated little by the presence/absence of light, and no shape abnormality occurs, unlike in the comparative examples. Namely, the semiconductor devices in the examples are more reliable than the semiconductor devices in the comparative examples.

The present invention is not limited to any of the above-described embodiments, and may be appropriately modified without departing from the gist of the present invention.

What is claimed is:

1. A manufacturing method of a semiconductor device, comprising:
forming an oxide semiconductor layer on an insulating layer, a part of the insulating layer being exposed from the oxide semiconductor layer;
performing a plasma process by use of chlorine-containing gas on the part of the insulating layer exposed from the oxide semiconductor layer; and
removing chlorine impurities from a surface layer of the exposed part of the insulating layer.

2. The manufacturing method of the semiconductor device according to claim 1, wherein the chlorine impurities are removed by a first etching process performed by use of fluorine-containing gas.

3. The manufacturing method of the semiconductor device according to claim 2, wherein the chlorine impurities are removed by half-etching performed on the exposed part of the insulating layer.

4. The manufacturing method of the semiconductor device according to claim 2, wherein the fluorine-containing gas contains CF₄ and CHF₃.

5. The manufacturing method of the semiconductor device according to claim 2, wherein the plasma process is a second etching process performed by use of chlorine-containing gas.

6. The manufacturing method of the semiconductor device according to claim 5, further comprising forming a conductive layer on the insulating layer and the oxide semiconductor layer;
wherein a part of the oxide semiconductor layer and a part of the insulating layer are exposed by the conductive layer being etched by the second etching process.

7. The manufacturing method of the semiconductor device according to claim 6, further comprising forming a gate electrode;
wherein the insulating layer is formed on the gate electrode.

8. A manufacturing method of a semiconductor device, comprising:
performing a plasma process by use of chlorine-containing gas on a part of an insulating layer, the part of the insulating layer being exposed;
removing chlorine impurities from a surface layer of the part of the insulating layer; and
forming an oxide semiconductor layer on the part of the insulating layer.

9. The manufacturing method of the semiconductor device according to claim 8, wherein the chlorine impurities are removed by a first etching process performed by use of fluorine-containing gas.

10. The manufacturing method of the semiconductor device according to claim 9, wherein the chlorine impurities are removed by half-etching performed on the part of the insulating layer.

11. The manufacturing method of the semiconductor device according to claim 9, wherein the fluorine-containing gas contains CF₄ and CHF₃.

12. The manufacturing method of the semiconductor device according to claim 9, wherein the plasma process is a second etching process performed by use of chlorine-containing gas.

13. The manufacturing method of the semiconductor device according to claim 12, further comprising forming a conductive layer on the insulating layer;
wherein the part of the insulating layer is exposed by the conductive layer being etched by the second etching process.

14. The manufacturing method of the semiconductor device according to claim 13, further comprising:
forming a gate insulating layer on the oxide semiconductor layer; and
forming a gate electrode on the gate insulating layer.

15. A semiconductor device, comprising:
a gate electrode;
a gate insulating layer on the gate electrode;
an oxide semiconductor layer facing the gate electrode with the gate insulating layer being therebetween; and
source and drain electrodes on the oxide semiconductor layer, the source and drain electrodes being connected with the oxide semiconductor layer;
wherein a part of the gate insulating layer exposed from the oxide semiconductor layer and the source and drain electrodes has a thickness smaller than that of a part of the gate insulating layer below the oxide semiconductor layer and a part of the gate insulating layer below the source and drain electrodes.

16. The semiconductor device according to claim 15, wherein the thickness of the part of the gate insulating layer below the oxide semiconductor layer is equal to the thickness of the part of the gate insulating layer below the source and drain electrodes.
